(19) United States
(12) Patent Application Publication
(10) Pub. No.: US 2001/0011987 A1
(43) Pub. Date: Aug. 9, 2001

(54) Shift register circuit capable of reducing consumption of power with reduced capacitive load of clock signal line and image display device including it

(76) Inventors: Yasushi Kubota, Sakurai-shi (JP); Hajime Washio, Tenri-shi (JP)

Correspondence Address: Dike, Bronstein, Roberts & Cushman, LLP, 130 Water Street, Boston, MA, 02109, US

(21) Appl. No.: 09/775,167

(22) Filed: Feb. 1, 2001

(30) Foreign Application Priority Data
Feb. 2, 2000 (JP) 2000-025221

(51) Int. Cl. G09G 3/36; H03K 19/0175

(52) U.S. Cl. 345/98; 345/92; 326/63

(57) ABSTRACT

There is provided a shift register circuit of a wide operation margin capable of reducing a capacitive load of a clock signal line, reducing a load of external circuits and achieving consumption power reduction and cost reduction with a simple construction, and an imaging display device including it. A plurality of serially connected register blocks BLK2 has a D-type flip-flop DFF1 that operates in synchronization with a clock signal, transfer gates TG11 and TG12 for controlling clock signals CK and /CK supplied to the D-type flip-flop DFF1 and an exclusive-OR circuit XOR1 that outputs a control signal to the transfer gates TG11 and TG12 so that the transfer gates are brought into an ON-state only in a specified period during which the output of the D-type flip-flop DFF1 changes i.e. when the input signal level and the output signal level of the D-type flip-flop DFF1 differ from each other.

### BACKGROUND OF THE INVENTION

The present invention relates to a shift register circuit including a flip-flop that operates in synchronization with a clock signal and to an image display device that employs the shift register circuit.

Conventionally, there have been provided various sorts of image display devices employing a shift register circuit, and reference is herein made, in particular, to an active matrix type liquid crystal display device. However, the image display device is not limited to the liquid crystal display device, and the other display device is used for a similar purpose in other fields.

An active matrix drive system is known as one drive system of the liquid crystal display devices of the conventional image display devices. As shown in FIG. 34, this liquid crystal display device is constructed of a pixel array ARY3, a scanning signal line drive circuit GD3, a data signal line drive circuit SD3, a precharge circuit PC3 and so on. The pixel array ARY3 includes a plurality of scanning signal lines GLₙ (n=1, 2, 3, . . . ) and a plurality of data signal lines SLₙ (n=1, 2, 3, . . . ) wherein the scanning signal lines GLₙ intersect the data signal lines SLₙ, and pixels PIX are arranged in a matrix form in respective portions enclosed by two adjacent scanning signal lines GLₙ and adjoining two data signal lines SLₙ. The data signal line drive circuit SD3 operates to sample an inputted video signal DAT in synchronization with a timing signal of a clock signal SCK or the like, amplify the signal as the need arises and write the resulting signal into each data signal line SLₙ. The scanning signal line drive circuit GD3 operates to write into each pixel PIX a video signal (data) written in each data signal line SLₙ by successively selecting the scanning signal lines GLₙ in synchronization with the timing signal of the clock signal GCK or the like so as to control the turning-on and -off of a switching element provided in the pixel PIX and retain the data written in each pixel PIX. The precharge circuit PC3 plays the role of assisting the writing of the video signal into the data signal line SLₙ by preliminarily charging the data signal line SLₙ before the writing of the video signal from the data signal line drive circuit SD3 into the data signal line SLₙ. This precharge circuit PC3 may sometimes be unnecessary depending on the specifications (screen size, number of pixels, input signal frequency, and so on) of the liquid crystal display device.

As shown in FIG. 35, each pixel PIX shown in FIG. 34 is constructed of a field effect transistor SW that serves as a switching element and a pixel capacitance (comprised of a liquid crystal capacitance CL and a supplementary capacitance CS). In FIG. 35, the data signal line SLₙ and one electrode of the pixel capacitance are connected to each other via the drain and source of the transistor SW that serves as the switching element, the gate of the transistor SW is connected to the scanning signal line GLₙ, and the other electrode of the pixel capacitance is connected to a common electrode common to all the pixels. Then, the liquid crystals whose transmittance or reflectance is modulated by a voltage applied to each liquid crystal capacity CL is used for display.

In the liquid crystal display device of the aforementioned active matrix type, an amorphous silicon thin film formed on a transparent substrate of glass or the like is used as a material of the pixel transistor SW, and the scanning signal line drive circuit GD3 and the data signal line drive circuit GD3 are each constructed of an external integrated circuit (IC).

In contrast to this, there has lately been reported a technique for monolithically forming a pixel array and drive circuits with a polysilicon thin film in response to the need for increasing the driving ability of pixel transistors in accordance with an increase in size of the screen, reducing the mounting cost of drive IC's, improving the reliability of mounting and so on. In addition, it has been tried to form elements of a polysilicon thin film on a glass substrate at a process temperature of not higher than the distortion point (about 600° C.) of the glass, intending for further increase in size of the screen and cost reduction. As shown in FIG. 36, there is provided, for example, a construction in which a pixel array ARY4, a scanning signal line drive circuit GD4, a data signal line drive circuit SD4 and a precharge circuit PC4 are mounted on an insulating substrate SUB, and in which an external control circuit CT4 and a supply voltage generating circuit VGEN4 are connected to them.

Next, reference is made to the construction of the data signal line drive circuit SD4. As for this data signal line drive circuit SD4, there have been known a dot-sequential drive system and a line-sequential drive system for different ways of writing image data into the data signal line. In a polysilicon TFT (thin film transistor) panel integrated with drive circuits, the dot-sequential drive system is often employed in terms of the simplicity of its circuit construction. Therefore, the data signal line drive circuit of the dot-sequential drive system will now be described below.

In this data signal line drive circuit of the dot-sequential drive system, as shown in FIG. 37, a video signal inputted to a video signal line DAT is written into data signal lines SL1 through SL4 by opening and closing a sampling switch AS3 in synchronization with an output pulse of a flip-flop FF7 of each stage of the shift register circuit constructed of a plurality of flip-flops FF7 (only four are shown in FIG. 37 for the sake of simplicity). In this case, buffer circuits NANDS and IV111 through IV113 are provided between the shift register circuit and the sampling switches AS3. The buffer circuits take in, retain and amplify the pulse signal outputted from the shift register circuit and generate an inverted signal as the need arises.

On the other hand, as shown in FIG. 38, the scanning signal line drive circuit outputs a scanning signal by subjecting the output pulse signal of the flip-flop FF8 of each stage of the shift register circuit constructed of a plurality of flip-flops FF8 (only four are shown in FIG. 38 for the sake of simplicity) to logic operation and amplification by means of buffer circuits NAND6, NOR3, IV121 and IV122.

The precharge circuit PC4 shown in FIG. 36 opens and closes the analog switch by a control signal PCT from a control circuit CT4 and preliminary charges the data signal lines SLₙ with the electric potential of the precharge signal PSG from the control circuit CT4.

As described above, the shift register circuit that successively transfers pulse signals is employed in each of the data signal line drive circuit and the scanning signal line drive circuit. This shift register circuit has a construction in which a plurality of flip-flops are connected in series and is driven by a clock signal CLK and a clock signal /CLK obtained by inverting the clock signal CLK. As a flip-flop FF constituting this shift register circuit, there is employed a D-type flip-flop or an SR-type (set and reset type) flip-flop.

In the shift register circuit employed in the data signal line drive circuit shown in FIG. 37 and the scanning signal line drive circuit shown in FIG. 38, the clock signals CLK and /CLK are inputted to all the flip-flops, and therefore, the load capacitance of the clock signal line becomes extremely large. This consequently causes a problem that an external IC (controller IC or the like) for driving the clock signal line is required to have a great driving capacity, leading to a cost increase and an increase in consumption of power.

In contrast to this, there has been proposed a shift register circuit (Japanese Patent Laid-Open Publication No. HEI 3-147598) of a construction such that, only when the output of the flip-flop of each stage of the shift register circuit is significant (in an active state), a clock signal is inputted to the flip-flop. As shown in FIG. 39, this shift register circuit has transfer gates TG141 and TG142 provided between the clock signal lines CK and /CK and each D-type flip-flop DFF7 and controls whether to connect or disconnect the clock signal lines CK and /CK to or from each D-type flip-flop DFF7 by a level composite signal of an output signal of each D-type flip-flop DFF7 and an output signal of the D-type flip-flop DFF7 of the preceding stage (a start signal only for the D-type flip-flop DFF7 of the first stage).

However, the above-mentioned shift register circuit having the construction shown in FIG. 39, the transfer gates TG141 and TG142 corresponding to the D-type flip-flops DFF7 of which the outputs are in the active state are all turned on (become conductive). Accordingly, there is the problem that many transfer gates TG141 and TG142 are put in the ON-state when the scanning pulse width of the shift register circuit is long, leading to a large capacitive load of the clock signal line.

FIGS. 40A through 40J and FIGS. 41A through 41J show signal waveforms depending on when the width of the pulse for scanning the shift register circuit is short and when the pulse width is long. In FIGS. 40A through 40J and FIGS. 41A through 41J are shown a start signal ST, a clock signal CK, control signals CTL1 through CTL4 and output signals OUT1 through OUT4.

Moreover, in recent years, there is a growing demand for reducing the amplitude of the input voltage for the simplification of the input interface, and it is effective to provide a built-in boost circuit (level shift circuit) for each flip-flop that constitute the shift register circuit, as a solution method.

If a current drive type level shift circuit (level shift circuit of the type in which a current is continuously flowing) is employed in order to increase the operation margin of the level shift circuit in this case, then it is effective to operate only the level shift circuit corresponding to the flip-flop of which the output is in the active state in order to reduce the consumption of current. However, a plurality of nodes in the shift register circuit become concurrently active when the scanning pulse width of the shift register circuit is long. Therefore, a plurality of level shift circuits are brought into the operating state, and there is a concern about the possible occurrence of a significant increase in the consumption of current, a voltage drop and troubles in the subsequent operation.

For example, in the aforementioned shift register circuit of the dot-sequential drive system, it is executed to increase the width of the pulse for driving the sampling switch in order to improve the writing performance of the video signal into the data signal line. In this case, a plurality of transfer gates are in the ON-state.

Moreover, when wide display (display region has an aspect ratio of 16:9) is performed in an image display device that has a display region of an aspect ratio of 3:4, it is required to provide a black display section (side black section) above and below the image display region. In order to write the image data for this side black section from the data signal line drive circuit, there is insufficient time for sequential write into the data signal line as in writing the normal video data, and it is required to bring all the sampling switches of the data signal line drive circuit into the ON-state. At the time, the consumption of current significantly increases since all the transfer gates are brought into the ON-state and all of the level shift circuits operate.

### SUMMARY OF THE INVENTION

Accordingly, the object of the present invention is to provide a shift register circuit of a wide operation margin capable of reducing the capacitive loads of a clock signal line, reducing the loads of external circuits and achieving consumption power reduction and cost reduction with a simple construction and an image display device including it.

In order to achieve the aforementioned object, the present invention provides a shift register circuit provided with a plurality of register blocks having a flip-flop that operates in synchronization with a clock signal and a transfer gate for controlling the clock signal supplied to the flip-flop,

the plurality of register blocks being serially connected together, and

the transfer gate being brought into an ON-state every register block only in a specified period during which an output of the flip-flop changes.

According to the shift register circuit of the above-mentioned construction, the clock signal is necessary only when the internal state of the flip-flop should be changed and is unnecessary when no change occurs. Therefore, inputting the clock signal to the flip-flop only in the necessary minimum period by bringing the transfer gate into the ON-state only in the specified period including a time point of change of the output of the flip-flop so as to control the clock signal supplied to the flip-flop enables the loads of the clock signal line to be remarkably reduced. As a result, consumption power reduction and cost reduction can be achieved with the reduced loads of the external circuit.

In one embodiment, when a level of an input signal inputted to each register block and a level of an output signal outputted from the register block differ from each other, the transfer gate of the register block is brought into the ON-state.

According to the shift register circuit of the above embodiment, the internal state of the flip-flop changes only when the level of the input signal inputted to the register block that has the flip-flop differs from the level of the output signal outputted from the register block, and the transfer gate is brought into the ON-state at the time.

In one embodiment, the flip-flop is a D-type flip-flop, and

the register block has a logic operation section for executing a logic operation of an input signal of the register block and an output signal of the register block and controls the transfer gate to be turned on and off based on a signal representing a logic operation result of the logic operation section.

According to the shift register circuit of the above embodiment, the logic operation section of the register block executes the logic operation of the input signal and the output signal of the register block, and a signal representing the logic operation result of the logic operation section becomes active (“1”) when the input signal level and the output signal level of the register block differ from each other. The transfer gate is made active or brought into the ON-state when the input signal level and the output signal level of the register block differ from each other based on the signal representing this logic operation result. For example, it is acceptable to bring the transfer gate into the ON-state only when the input signal level and the output signal level of the register block differ from each other by means of an exclusive-OR circuit employed as the logic operation section or to provide the logic operation section by combining other logic operation elements, which are not limited to the exclusive-OR circuit.

In one embodiment, the flip-flop is an SR-type flip-flop,

the transfer gate is comprised of a first transfer gate for controlling input of the clock signal inputted to a set terminal of the SR-type flip-flop and a second transfer gate for controlling input of the clock signal inputted to a reset terminal of the SR-type flip-flop, and

the register block has a first logic operation section and a second logic operation section for executing a logic operation of an input signal of the register block and an output signal of the register block, controls the first transfer gate to be turned on and off based on a signal that represents a logic operation result of the first logic operation section and controls the second transfer gate to be turned on and off based on a signal that represents a logic operation result of the second logic operation section.

According to the shift register circuit of the above embodiment, the first logic operation section of the register block executes the logic operation of the input signal and the output signal of the register block. Only when this register block has the input signal “1” different from the output signal “0” thereof, the first transfer gate is made active or brought into the ON-state based on the signal that represents the logic operation result of the first logic operation section, and the clock signal is inputted to the set terminal of the flip-flop to set the output signal to the same logic (“1”) as that of the input signal. On the other hand, only when this register block has the input signal “0” different from the output signal “1” thereof, the second transfer gate is made active or brought into the ON-state based on the signal that represents this logic operation result of the second logic operation section, and the clock signal is inputted to the reset terminal of the flip-flop to reset the output signal to the same logic (“0”) as that of the input signal. It is acceptable to bring either one of the first and second transfer gates into the ON-state only when the input signal level and the output signal level of the register block differ from each other by using, for example, an OR circuit as the aforementioned first and second logic operation sections or provide the first and second logic operation sections by combining other logic operation elements, which are not limited to the OR circuit.

In one embodiment, the register block has a retainment signal circuit that inputs to a clock input terminal of the flip-flop of the register block a retainment signal for bringing the output of the flip-flop into a retained state in a period during which the transfer gate is in an OFF-state.

According to the shift register circuit of the above embodiment, it is possible that the flip-flop might malfunction due to an internal leak current, an external noise or the like if the clock input terminal comes to have a high impedance when the transfer gate is in the OFF-state. However, by inputting the retainment signal of the level at which the flip-flop state is retained (not changed) from the retainment signal circuit to the clock input terminal of the flip-flop when there is no clock signal input, the malfunction of the flip-flop can be prevented.

The present invention also provides an image display device comprising a plurality of pixels arranged in a matrix form, a plurality of data signal lines for supplying image data to be written into the plurality of pixels, a plurality of scanning signal lines for controlling the image data to be written into the pixels, a data signal line drive circuit for driving the data signal lines and a scanning signal line drive circuit for driving the scanning signal lines, wherein

at least one of the data signal line drive circuit and the scanning signal line drive circuit includes any one of the shift register circuits.

According to the image display device of the above-mentioned construction, the shift register circuit is employed for at least one of the data signal line drive circuit and the scanning signal line drive circuit, and this allows the consumption power reduction and cost reduction of the image display device to be achieved.

In one embodiment, an output pulse width of the data signal line drive circuit is controlled by controlling a pulse width of an input signal inputted to the register block of the first stage of the shift register circuit.

According to the image display device of the above embodiment, the clock signal is inputted to the flip-flop only when the input signal level and the output signal level of the register block differ from each other. Therefore, the number of the flip-flops to which the clock signal is inputted is restrained to the minimum (two or less), and this allows the consumption power reduction and cost reduction of the image display device to be achieved.

In one embodiment, a side black region is displayed on an upper side and a lower side of an image display screen by writing a black signal into all the data signal lines while increasing the pulse width of the input signal inputted to the register block of the first stage of the shift register circuit so that all the data signal lines are brought into an active state by the data signal line drive circuit.

According to the image display device of the above embodiment, the clock signal is inputted to the flip-flop only when the input signal level and the output signal level of the register block differ from each other even in the case where the pulse width of the input signal to be inputted to the register block of the first stage is increased. Therefore, the number of the flip-flops to which the clock signal is inputted is restrained to the minimum (two or less), and this allows the consumption power reduction and cost reduction of the image display device to be achieved.

In one embodiment, at least one of the data signal line drive circuit and the scanning signal line drive circuit is formed on a substrate identical to that of the plurality of pixels.

According to the image display device of the above embodiment, at least one of the data signal line drive circuit and the scanning signal line drive circuit is formed on the same substrate as that of the pixels through the same processes, and this allows the mounting cost reduction and the improvement of reliability of the drive circuit to be achieved.

In one embodiment, an active element constituting at least the data signal line drive circuit is provided by a polysilicon thin film transistor.

According to the image display device of the above embodiment, the active elements (transistors) of at least the data signal line drive circuit are formed by using the above-mentioned polysilicon thin film, and, therefore an extremely high driving power characteristic can be obtained by comparison with the amorphous silicon thin film transistor that has been employed in the conventional active matrix liquid crystal display device or the like, and the pixels and the data signal line drive circuit can easily be formed on an identical substrate. With this arrangement, the effects of reducing the fabricating cost and the mounting cost and increasing the mounting yield can be expected.

In one embodiment, the active element is formed on a glass substrate through a process at a temperature of not higher than 600° C.

According to the image display device of the above embodiment, forming the polysilicon thin film transistor through the process at a temperature of not higher than 600° C. provides the merit that a large-size image display device capable of employing glass, which is inexpensive and easily increased in size and has a low distortion point temperature, as a substrate can be fabricated at low cost.

In one embodiment, the clock signal has a level lower than a clock signal input level of the flip-flop,

the register block has a level shift circuit for shifting a level of the clock signal so that the level of the clock signal becomes not lower than the clock signal input level of the flip-flop, and

the level shift circuit is brought into an operating state every register block only in a specified period during which the output of the flip-flop changes.

According to the shift register circuit of the above embodiment, the clock signal is necessary only when the internal state of the flip-flop should be changed and is unnecessary when no change occurs. Therefore, inputting the clock signal to the level shift circuit in the necessary minimum period with the level shift circuit brought into the operating state only in the specified period during which the output of the flip-flop changes enables the loads of the clock signal line to be remarkably reduced. Furthermore, stopping the operation of the level shift circuit in the period during which the internal state of the flip-flop does not change prevents the through current from flowing through the level shift circuit, and this allows the consumption of power to be remarkably reduced. As a result, consumption power reduction and cost reduction can be achieved with the reduced loads of the external circuit.

In the shift register circuit of one embodiment, when a level of an input signal inputted to each register block and a level of an output signal outputted from the register block differ from each other, the transfer gate of the register block is brought into the ON-state, and

when a level of an input signal inputted to each register block and a level of an output signal outputted from the register block differ from each other, the level shift circuit of the register block is brought into an operating state.

According to the shift register circuit of the above embodiment, the internal state of the flip-flop changes when the level of the input signal inputted to the register block differs from the level of the output signal, and the level shift circuit is brought into the ON-state at the time.

In one embodiment, the register block has a retainment signal circuit that inputs to a clock input terminal of the flip-flop of the register block a retainment signal for bringing the output of the flip-flop into a retained state in a period during which the transfer gate is in an OFF-state.

According to the shift register circuit of the above embodiment, it is possible that the flip-flop might malfunction due to an internal leak current, an external noise or the like if the clock input terminal comes to have a high impedance when the transfer gate is in the OFF-state. However, by inputting the retainment signal of the level at which the flip-flop state is retained (not changed) from the retainment signal circuit to the clock input terminal of the flip-flop when there is no clock signal input, the malfunction of the flip-flop can be prevented.

In one embodiment, the register block has an OFF-state signal circuit that inputs to the clock input terminal of the level shift circuit an OFF-state signal of a level at which no current flows through the level shift circuit in the period during which the transfer gate is in the OFF-state.

According to the shift register circuit of the above embodiment, the internal state of the flip-flop does not change when the transfer gate is in the OFF-state, and therefore, the level shift circuit is not required to be operated. Therefore, it is very effective for reducing the consumption of current of the level shift circuit to set the potential level of the input node (clock input terminal) of the level shift circuit to a level at which no current flows.

In one embodiment, the level shift circuit is connected to a power source line and a ground line, and

the register block has a disconnecting circuit for disconnecting either one of the power source line and the ground line of the level shift circuit in the period during which the transfer gate is in the OFF-state.

According to the shift register circuit of the above embodiment, the internal state of the flip-flop does not change when the transfer gate is in the OFF-state, and therefore, the level shift circuit is not required to be operated. Therefore, it is very effective for reducing the consumption of current of the level shift circuit to cut off the current path of the level shift circuit by the disconnecting circuit.

In one embodiment, the flip-flop is a D-type flip-flop, and

the register block has a logic operation section for executing a logic operation of an input signal and an output signal of the register block and controls the transfer gate to be turned on and off based on a signal representing a logic operation result of the logic operation section.

According to the shift register circuit of the above embodiment, the logic operation section of the register block executes the logic operation of the input signal and the output signal of the register block, and a signal representing the logic operation result of the logic operation section becomes active (“1”) when the input signal level and the output signal level of the register block differ from each other. The transfer gate is made active or brought into the ON-state when the input signal level and the output signal level of the register block differ from each other based on the signal representing this logic operation result. For example, it is acceptable to bring the transfer gate into the ON-state only when the input signal level and the output signal level of the register block differ from each other by means of an exclusive-OR circuit employed as the logic operation section or to provide the logic operation section by combining other logic operation elements, which are not limited to the exclusive-OR circuit.

In one embodiment, the flip-flop is an SR-type flip-flop,

the transfer gate is comprised of a first transfer gate for controlling the input of the clock signal inputted to a set terminal of the SR-type flip-flop and a second transfer gate for controlling the input of the clock signal inputted to a reset terminal of the SR-type flip-flop, and

the register block has a first logic operation section and a second logic operation section for executing a logic operation of an input signal and an output signal of the register block, controls the first transfer gate to be turned on and off based on a signal that represents a logic operation result of the first logic operation section and controls the second transfer gate to be turned on and off based on a signal that represents a logic operation result of the second logic operation section.

According to the shift register circuit of the above embodiment, the first logic operation section of the register block executes the logic operation of the input signal and the output signal of the register block. Only when this register block has the input signal “1” different from the output signal “0” thereof, the first transfer gate is made active or brought into the ON-state based on the signal that represents the logic operation result of the first logic operation section, and the clock signal is inputted to the set terminal of the flip-flop to set the output signal to the same logic (“1”) as that of the input signal. On the other hand, only when this register block has the input signal “0” different from the output signal “1” thereof, the second transfer gate is made active or brought into the ON-state based on the signal that represents this logic operation result of the second logic operation section, and the clock signal is inputted to the reset terminal of the flip-flop to reset the output signal to the same logic (“0”) as that of the input signal. It is acceptable to bring either one of the first and second transfer gates into the ON-state only when the input signal level and the output signal level of the register block differ from each other by using, for example, an OR circuit as the aforementioned first and second logic operation sections or provide the first and second logic operation sections by combining other logic operation elements, which are not limited to the OR circuit.

The present invention also provides an image display device comprising a plurality of pixels arranged in a matrix form, a plurality of data signal lines for supplying image data to be written into the pixels, a plurality of scanning signal lines for controlling the image data to be written into the pixels, a data signal line drive circuit for driving the data signal lines and a scanning signal line drive circuit for driving the scanning signal lines,

at least one of the data signal line drive circuit and the scanning signal line drive circuit includes any one of the shift register circuits.

According to the image display device of the above-mentioned construction, the shift register circuit is employed for at least one of the data signal line drive circuit and the scanning signal line drive circuit, and this allows the consumption power reduction and cost reduction of the image display device to be achieved.

In the image display device of one embodiment, an output pulse width of the data signal line drive circuit is controlled by controlling a pulse width of an input signal inputted to the register block of the first stage of the shift register circuit.

According to the image display device of the above embodiment, the clock signal is inputted to the flip-flop only when the input signal level and the output signal level of the register block differ from each other. Therefore, the number of the flip-flops to which the clock signal is inputted is restrained to the minimum (two or less), and this allows the consumption power reduction and cost reduction of the image display device to be achieved.

In one embodiment, a side black region is displayed on an upper side and a lower side of an image display screen by writing a black signal into all the data signal lines while increasing the pulse width of the input signal inputted to the register block of the first stage of the shift register circuit so that all the data signal lines are brought into an active state by the data signal line drive circuit.

According to the image display device of the above embodiment, the clock signal is inputted to the flip-flop only when the input signal level and the output signal level of the register block differ from each other even in the case where the pulse width of the input signal to be inputted to the register block of the first stage is increased. Therefore, the number of the flip-flops to which the clock signal is inputted is restrained to the minimum (two or less), and this allows the consumption power reduction and cost reduction of the image display device to be achieved.

In the image display device of one embodiment, at least one of the data signal line drive circuit and the scanning signal line drive circuit is formed on a substrate identical to that of the pixels.

According to the image display device of the above embodiment, at least one of the data signal line drive circuit and the scanning signal line drive circuit is formed on the same substrate as that of the pixels through the same processes, and this allows the mounting cost reduction and the improvement of reliability of the drive circuit to be achieved.

In the image display device of one embodiment, an active element constituting at least the data signal line drive circuit is provided by a polysilicon thin film transistor.

According to the image display device of the above embodiment, the active elements (transistors) of at least the data signal line drive circuit are formed by using the above-mentioned polysilicon thin film, and, therefore then an extremely high driving power characteristic can be obtained by comparison with the amorphous silicon thin film transistor that has been employed in the conventional active matrix liquid crystal display device or the like, and the pixels and the data signal line drive circuit can easily be formed on an identical substrate. With this arrangement, the effects of reducing the fabricating cost and the mounting cost and increasing the mounting yield can be expected.

In the image display device of one embodiment, the active element is formed on a glass substrate through a process at a temperature of not higher than 600° C.

According to the image display device of the above embodiment, forming the polysilicon thin film transistor through the process at a temperature of not higher than 600° C. provides the merit that a large-size image display device capable of employing glass, which is inexpensive and easily increased in size and has a low distortion point temperature, as a substrate can be fabricated at low cost.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a block diagram showing the construction of a shift register circuit according to a first embodiment of the present invention;

FIGS. 2A through 2J are charts showing the signal waveforms of the shift register circuit shown in FIG. 1;

FIG. 3 is a block diagram showing a shift register circuit according to a second embodiment of the present invention;

FIG. 4 is a circuit diagram of a D-type flip-flop constituting part of the shift register circuit shown in FIG. 3;

FIGS. 5A through 5K are charts showing the signal waveforms of the shift register circuit shown in FIG. 3;

FIG. 6 is a block diagram showing a shift register circuit according to a third embodiment of the present invention;

FIG. 7 is a circuit diagram of an SR-type flip-flop constituting part of the shift register circuit shown in FIG. 6;

FIGS. 8A through 8M are charts showing the signal waveforms of the shift register circuit shown in FIG. 6;

FIG. 9 is a block diagram showing the construction of a shift register circuit according to a fourth embodiment of the present invention;

FIG. 10 is a block diagram showing the construction of an image display device according to a fifth embodiment of the present invention;

FIG. 11 is a block diagram showing the construction of a data signal line drive circuit of the image display device shown in FIG. 10;

FIG. 12 is a block diagram of a scanning signal line drive circuit of the image display device shown in FIG. 10;

FIGS. 13A through 13J are charts showing the signal waveforms of the data signal line drive circuit shown in FIG. 11;

FIGS. 14A through 14J are charts showing the signal waveforms of the data signal line drive circuit shown in FIG. 11;

FIG. 15 is a block diagram showing the construction of a shift register circuit according to a sixth embodiment of the present invention;

FIGS. 16A through 16J are charts showing the signal waveforms of the shift register circuit shown in FIG. 15;

FIG. 17 is a block diagram showing the construction of a shift register circuit according to a seventh embodiment of the present invention;

FIGS. 18A through 18K are charts showing the signal waveforms of the shift register circuit shown in FIG. 17;

FIG. 19 is a circuit diagram of a level shift circuit of the above shift register circuit;

FIG. 20 is a circuit diagram of a level shift circuit of the above shift register circuit;

FIG. 21 is a block diagram showing the construction of a shift register circuit according to an eighth embodiment of the present invention;

FIGS. 22A through 22M are charts showing the signal waveforms of the shift register circuit shown in FIG. 21;

FIG. 23 is a block diagram showing the construction of a shift register circuit according to a ninth embodiment of the present invention;

FIG. 24 is a block diagram showing the construction of a shift register circuit according to a tenth embodiment of the present invention;

FIG. 25 is a circuit diagram of a level shift circuit of the above shift register circuit;

FIG. 26 is a block diagram showing the construction of a shift register circuit according to an eleventh embodiment of the present invention;

FIG. 27 is a block diagram of a data signal line drive circuit of an image display device according to a twelfth embodiment of the present invention;

FIG. 28 is a block diagram of the scanning signal line drive circuit of the above image display device;

FIGS. 29A through 29J are charts showing the signal waveforms of the data signal line drive circuit shown in FIG. 27;

FIGS. 30A through 30J are charts showing the signal waveforms of the data signal line drive circuit shown in FIG. 27;

FIG. 31 is a block diagram showing the construction of an image display device according to a thirteenth embodiment of the present invention;

FIG. 32 is a sectional view showing the construction of a polysilicon thin film transistor of the above image display device;

FIGS. 33A through 33K are views showing the fabricating processes of the polysilicon thin film transistor shown in FIG. 32;

FIG. 34 is a block diagram showing the construction of a prior art image display device;

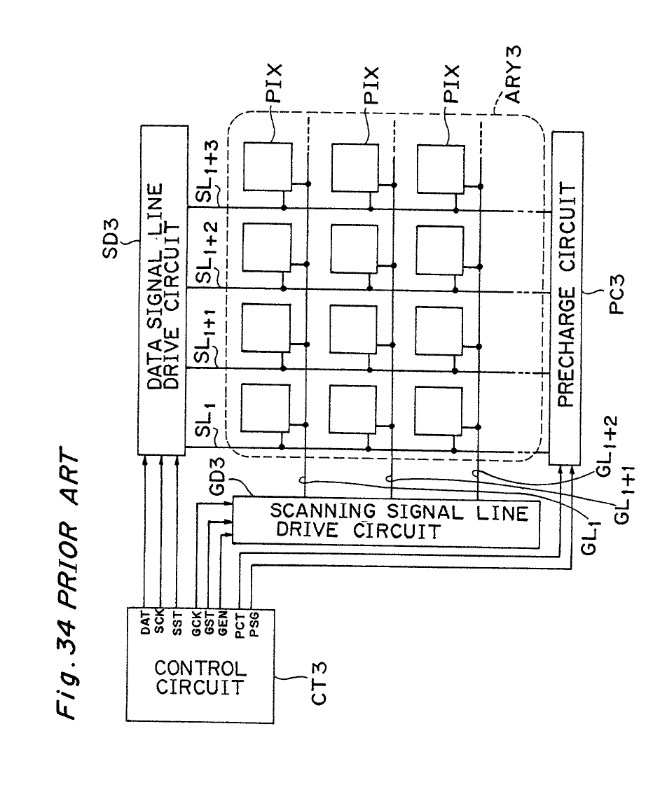

FIG. 35 is a view showing the internal construction of a pixel that constitutes part of the above image display device;

FIG. 36 is a block diagram showing the construction of another prior art image display device;

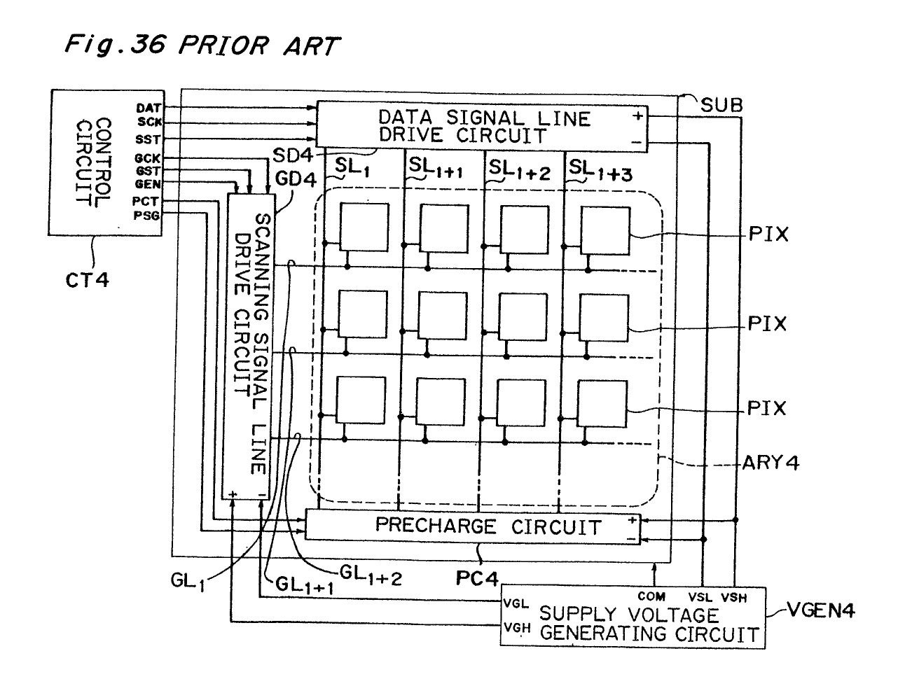

FIG. 37 is a block diagram of a prior art data signal line drive circuit;

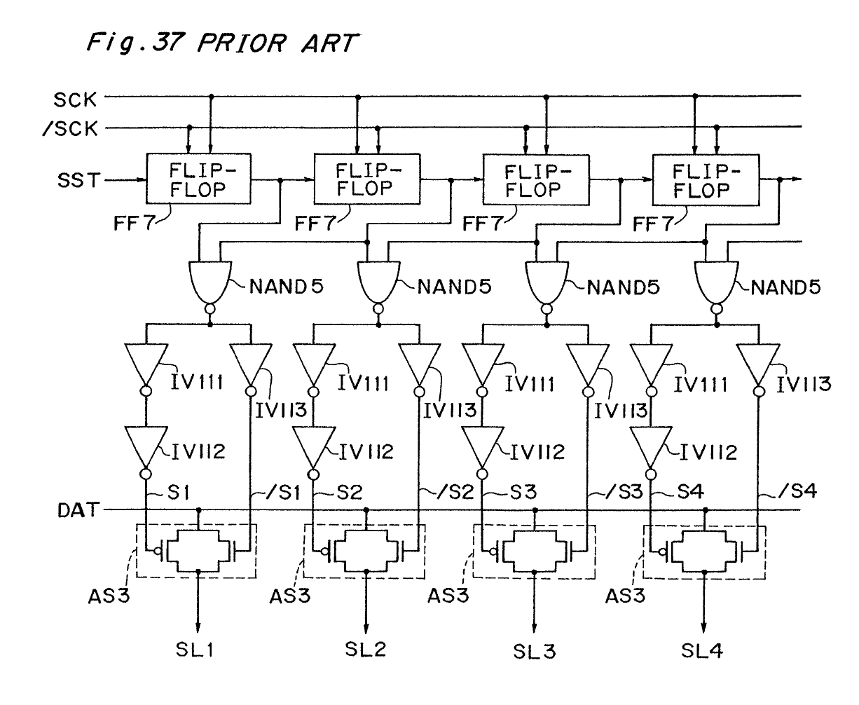

FIG. 38 is a block diagram of a prior art scanning signal line drive circuit;

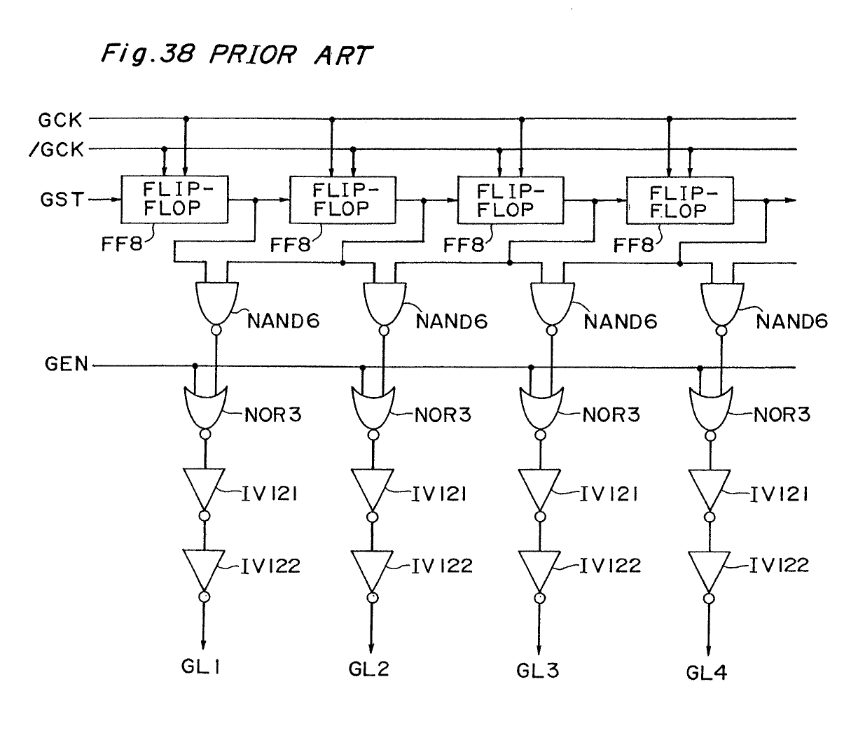

FIG. 39 is a block diagram showing the construction of a prior art shift register circuit;

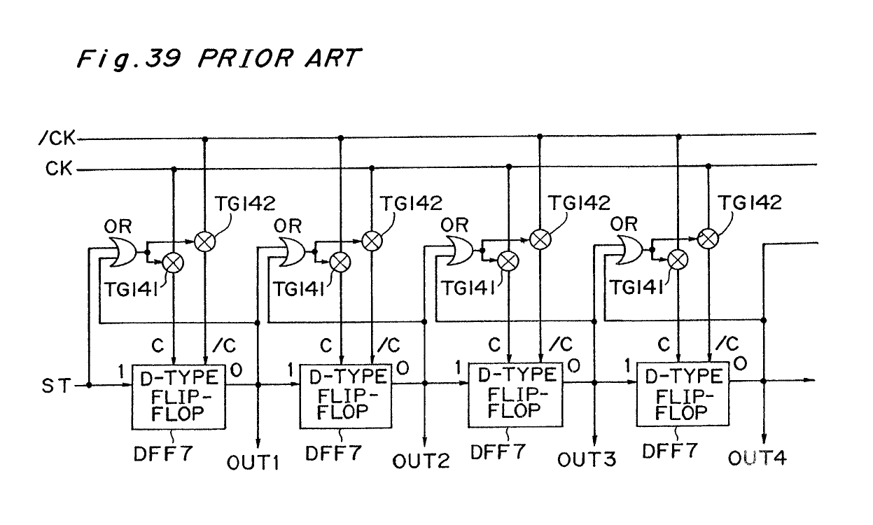

FIGS. 40A through 40J are charts showing the signal waveforms of the shift register circuit shown in FIG. 39; and

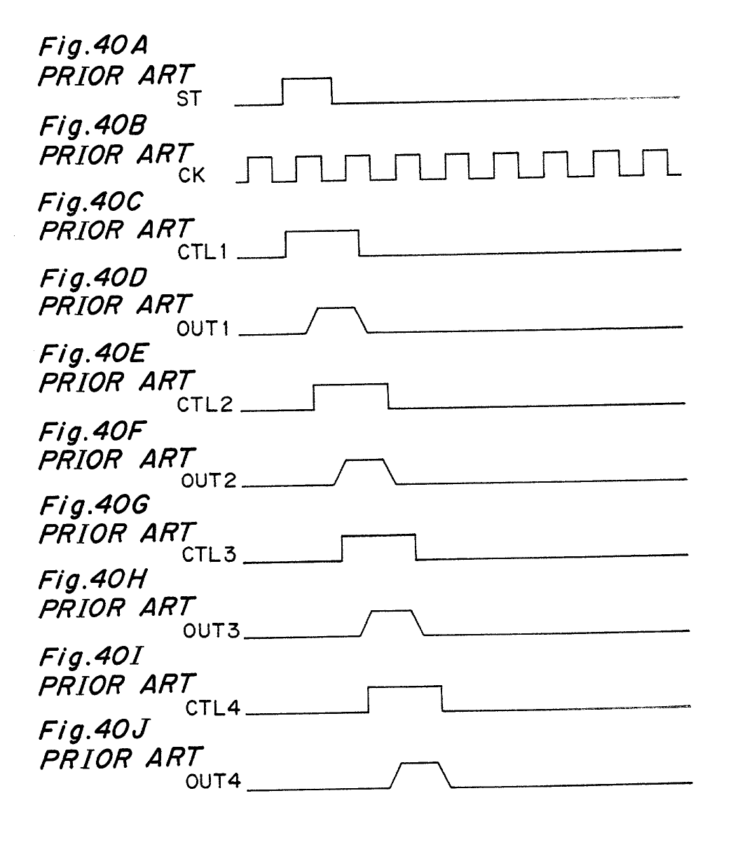

FIGS. 41A through 41J are charts showing other signal waveforms of the shift register circuit shown in FIG. 39.

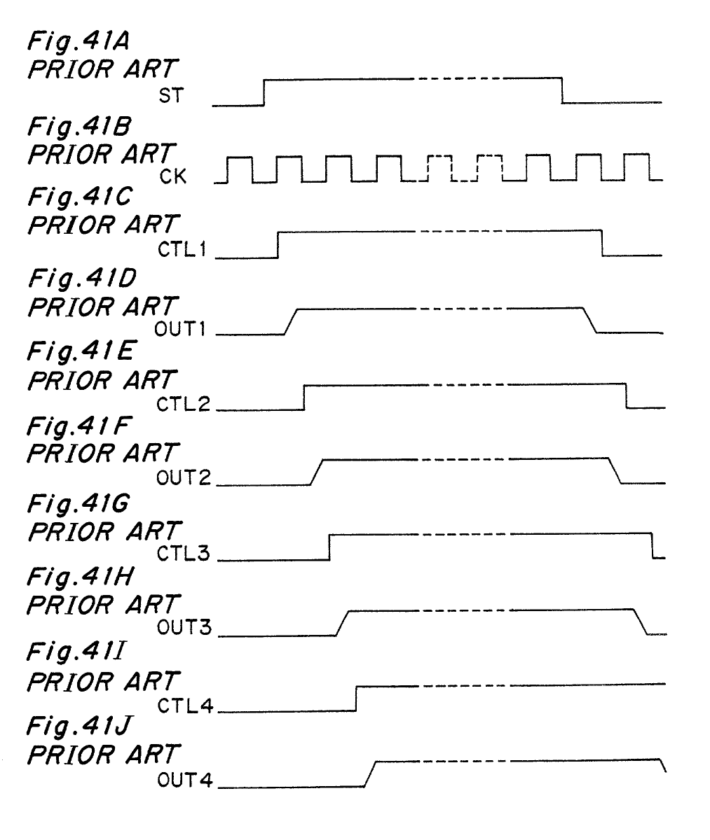

### DETAILED DESCRIPTION OF THE PREFERRED EMBODIMENTS

The shift register circuits and image display devices of the present invention will be described in detail below on the basis of the embodiments thereof shown in the drawings.

(First Embodiment)

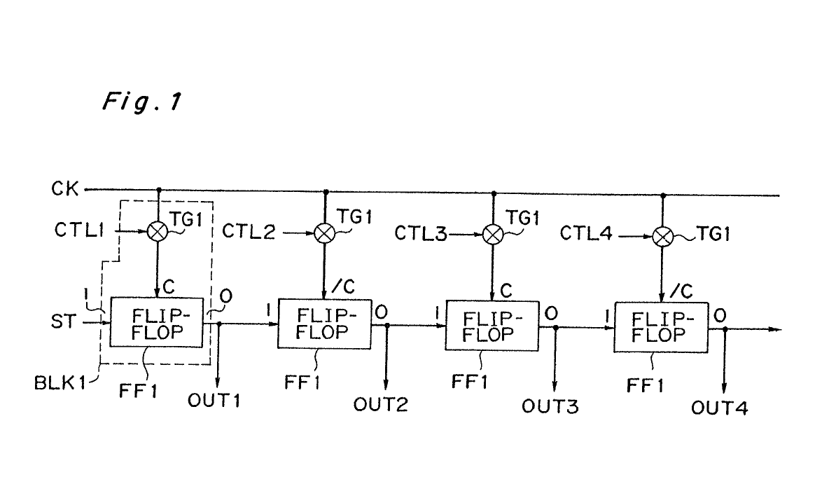

FIG. 1 is a block diagram showing the construction of the shift register circuit of the first embodiment of the present invention. As shown in FIG. 1, this shift register circuit has a plurality of serially connected flip-flops FF1 (only four are shown in FIG. 1 for the sake of simplicity) and a transfer gate TG1 provided for each flip-flop FF1. The transfer gate TG1 is controlled to be turned on (conductive) and off (nonconductive) by a control signal (only CTL1 through CTL4 are shown in FIG. 1 for the sake of simplicity), and a clock signal CK is inputted to the flip-flops FF1 via this transfer gate TG1. A register block BLK1 is constructed of the flip-flop FF1 and the transfer gate TG1. The clock signal CK is inputted to clock input terminals C of the flip-flops FF1 of the odd-number register blocks BLK1 from the input side, while the clock signal CK is inputted to clock input terminals /C of the flip-flops FF1 of the even-number register blocks BLK1.

When a start signal ST is inputted, the shift register circuit of the above-mentioned construction sequentially outputs output signals (only output signals OUT1 through OUT4 are shown in FIG. 1) from the flip-flops FF1 in synchronization with the clock signal.

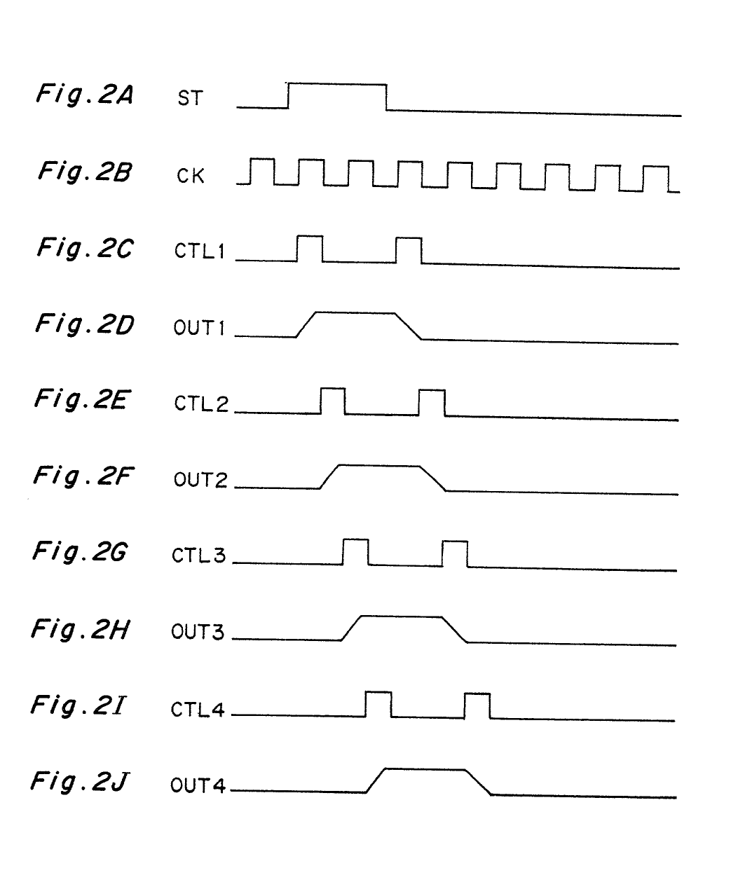

FIGS. 2A through 2J show the signal waveforms of the above-mentioned shift register circuit. As shown in FIGS. 2A through 2J, the control signals CTL1 through CTL4 are set so as to become active only when the internal state of the corresponding flip-flop FF1 (shown in FIG. 1) changes (when the output signals OUT1 through OUT4 change). Therefore, only when the output signal of the corresponding flip-flop FF1 changes, the clock signal CK is inputted to the flip-flop FF1.

The flip-flops FF1 operate normally if the clock signal is supplied at least in accordance with a timing of change of the internal state. Therefore, the control signals CTL1 through CTL4 shown in FIGS. 2C, 2E, 2G and 2I are sufficient. With this arrangement, the period during which the clock signal CK is inputted can be shortened, and therefore, the loads of the clock signal line can be restrained to the minimum.

(Second Embodiment)

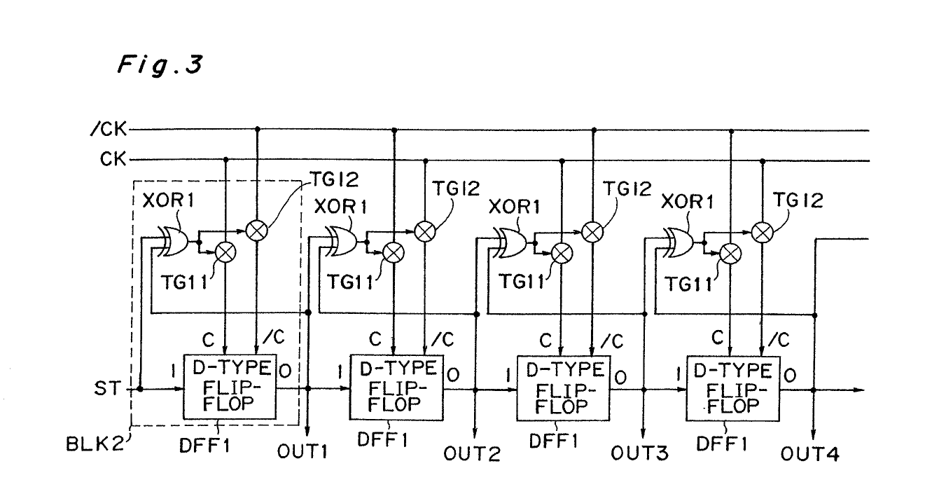

The control signals (CTL1 through CTL4) in FIGS. 2C, 2E, 2G and 2I of the first embodiment become active only in the period during which the input signal level and the output signal level of the flip-flop FF1 differ from each other. The internal state of each flip-flop changes only when the input signal level and the output signal level of the flip-flop differ from each other. Therefore, the shift register circuit of the second embodiment of the present invention shown in FIG. 3 detects whether or not the input signal level and the output signal level of the flip-flop differ from each other and use the resulting signal as a control signal for the transfer gate.

As shown in FIG. 3, there are provided a plurality of serially connected D-type flip-flops DFF1 (only four are shown in FIG. 3 for the sake of simplicity), transfer gates TG11 and TG12 provided for each D-type flip-flop DFF1 and an exclusive-OR circuit XOR1 that serves as a logic operation section provided for each D-type flip-flop DFF1, The input terminal of the D-type flip-flop DFF1 is connected to one input terminal of the exclusive-OR circuit XOR1, and the output terminal of the D-type flip-flop DFF1 is connected to the other input terminal of the exclusive-OR circuit XOR1. The output terminal of the exclusive-OR circuit XOR1 is connected to the control input terminals of the transfer gates TG11 and TG12. The transfer gate TG11 is controlled to be turned on and off by an exclusive-OR signal outputted from the exclusive-OR circuit XOR1, and the clock signal CK (clock signal /CK for each even-number D-type flip-flop DFF1) is inputted to the clock input terminal C of the D-type flip-flop DFF1 via this transfer gate TGl1. The transfer gate TG12 is controlled to be turned on and off by the exclusive-OR signal outputted from the exclusive-OR circuit XOR1, and the clock signal /CK (clock signal CK for each even-number D-type flip-flop DFF1) is inputted to the clock input terminal /C of the D-type flip-flop DFF1 via this transfer gate TG12. Therefore, only when the input signal level and the output signal level of the D-type flip-flop DFF1 differ from each other, the transfer gates TG11 and TG12 are turned on (become conductive). A register block BLK2 is constructed of the D-type flip-flop DFF1, the transfer gates TG11 and TG12 and the exclusive-OR circuit XOR1.

In this second embodiment, the control signal of the transfer gates TG11 and TG12 is the exclusive-OR signal. However, without being limited to this, the control signal may be an inverted signal obtained by inverting the exclusive-OR signal depending on the control signal conditions of the transfer gates, and both the signals may also be used (the same thing can be said for the other embodiments hereinbelow).

Although the exclusive-OR circuit XOR1 is employed as the logic operation section in the second embodiment, the logic operation section can also be provided by combining other logic operators.

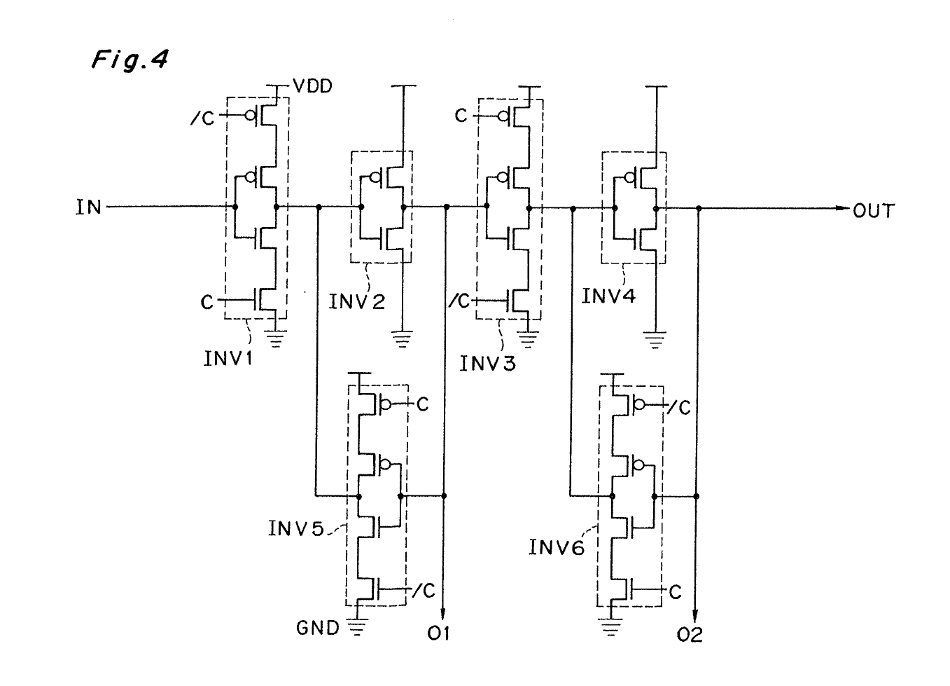

FIG. 4 shows the construction of the D-type flip-flop DFF1 that constitutes the shift register circuit shown in FIG. 3. Adjoining two D-type flip-flops are shown in FIG. 4.

As shown in FIG. 4, these D-type flip-flops have a clocked inverter INV1, an inverter INV2, a clocked inverter INV3 and an inverter INV4, which are connected in series, a clocked inverter INV5 the input terminal of which is connected to the output terminal of the inverter INV2 and the output terminal of which is connected to the input terminal of the inverter INV2 and a clocked inverter INV6 the input terminal of which is connected to the output terminal of the inverter INV4 and the output terminal of which is connected to the input terminal of the inverter INV4. The inverters INV1 through INV6 are constructed of CMOS (complementary metal oxide semiconductor) transistors. One D-type flip-flop is constructed of the clocked inverter INV1, the inverter INV2 and the clocked inverter INV5, while one D-type flip-flop is constructed of the clocked inverter INV3, the inverter INV4 and the clocked inverter INV6.

The clock signal /C is inputted to the clock input terminals located on the PMOS side of the clocked inverters INV1 and INV6, while the clock signal C is inputted to the clock input terminals located on the NMOS side thereof. The clock signal C is input to the clock input terminals located on the PMOS side of the clocked inverters INV3 and INV5, while the clock signal /C is inputted to the clock input terminals located on the NMOS side thereof.

As described above, the D-type flip-flop is constructed of one inverter and two clocked inverters, and the clock signals of mutually inverted phases are inputted to the two clocked inverters. Then, the clock signals of mutually inverted phases are inputted to adjoining D-type flip-flops.

In this D-type flip-flop constructed of the clocked inverter INV1, the inverter INV2 and the clocked inverter INV5, an input signal IN is transferred as an output signal O1 to the next stage when the clock signals CK and /CK are active, and the internal state is retained when the clock signals CK and /CK are inactive, not changing an output signal O2.

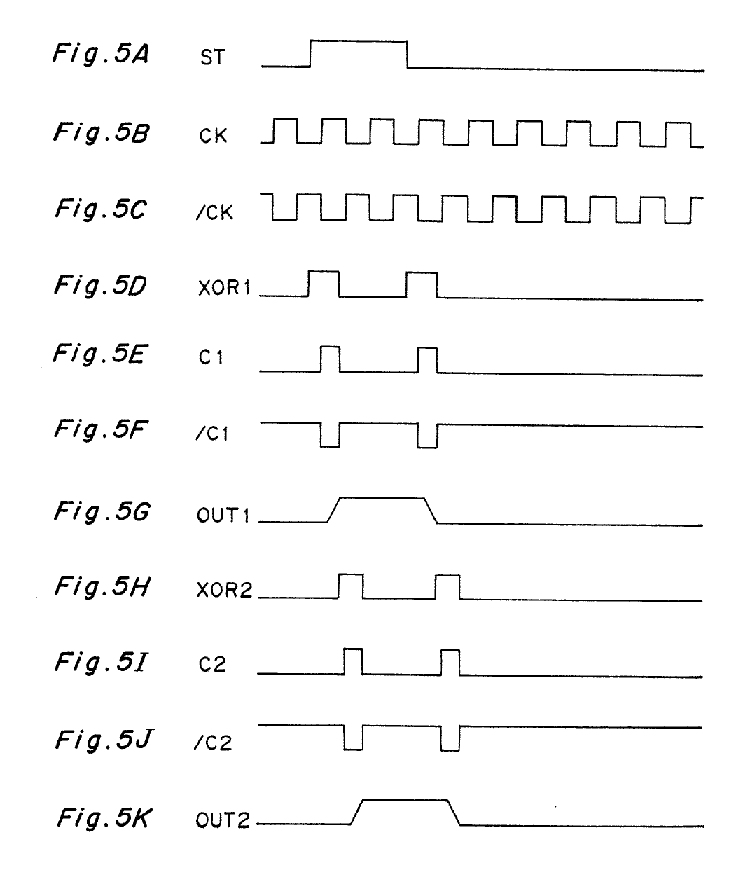

FIGS. 5A through 5K show the signal waveforms of the shift register circuit shown in FIG. 3. In FIGS. 5A, 5D, 5G, 5H and 5K, the exclusive-OR signals (XOR1 and XOR2 in FIGS. 5D and 5H) that are the control signals are active when the input signal level and the output signal level of a register block BLK2 differ from each other, i.e., when the input signal level and the output signal level of the D-type flip-flop DFF1 differ from each other. The internal clock signals (C1, C2, /C1 and /C2 in FIGS. 5E, 5I, 5F and 5J and 5K) of the D-type flip-flop DFF1 (shown in FIG. 3) are inputted only in the period during which the exclusive-OR signals (XOR1 and XOR2 in FIGS. 5D and 5H) are active. It is to be noted that the exclusive-OR signal XOR1, the internal clock signals C1 and /C1 and the output signal OUT1 represent signals relevant to the register block BLK2 of the first stage, while the exclusive-OR signal XOR2, the internal clock signals C2 and /C2 and the output signal OUT2 represent signals relevant to the register block BLK2 of the second stage. Although the signal waveforms relevant to the register block BLK2 of the third and subsequent stages are not shown in the figures, the same thing as described above can be said.

As described above, the transfer gates TG11 and TG12 can be made active (brought into the ON-state) when the input signal level and the output signal level of the register block BLK2 differ from each other with a simple construction employing the exclusive-OR circuit XOR1.

(Third Embodiment)

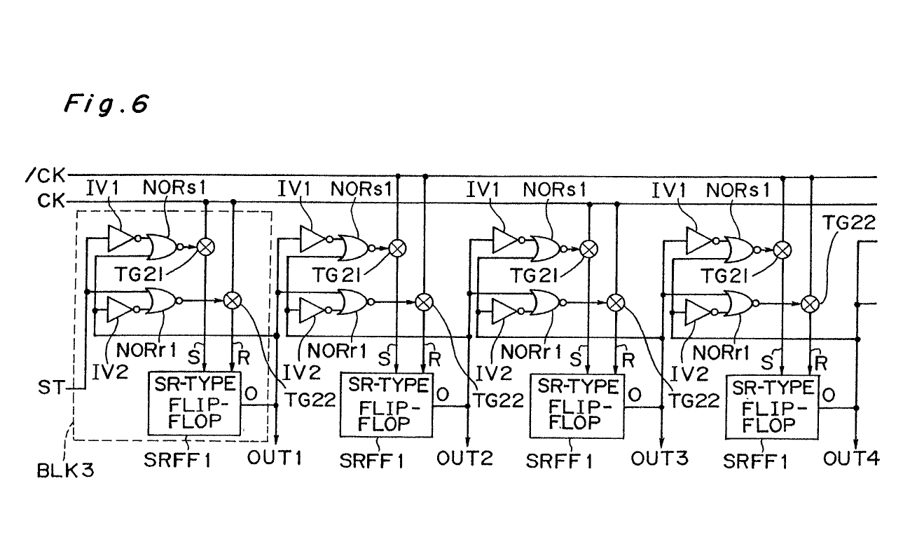

FIG. 6 shows a block diagram of the shift register circuit of the third embodiment of the present invention. As shown in FIG. 6, there are provided a plurality of serially connected SR-type flip-flops SRFF1 (only four are shown in FIG. 6 for the sake of simplicity), transfer gates TG21 and TG22 provided for each SR-type flip-flop SRFF1, a NOR circuit NORs1 that serves as a first logic operation section provided for each SR-type flip-flop SRFF1, a NOR circuit NORr1 that serves as a second logic operation section provided for each SR-type flip-flop SRFF1 and inverters IV1 and IV2. The output signal of the SR-type flip-flop SRFF1 of the preceding stage (or a start signal ST only in the first stage) is inputted to one input terminal of the NOR circuit NORs1 via the inverter IV1, and the output terminal of the SR-type flip-flop SRFF1 is connected to the other input terminal of the NOR circuit NORs1. The output terminal of the NOR circuit NORs1 is connected to the control input terminal of the transfer gate TG21. The output signal of the SR-type flip-flop SRFF1 of the preceding stage (or the start signal ST for only the SR-type flip-flop SRFF1 of the first stage) is inputted to one input terminal of the NOR circuit NORr1, and the output terminal of the SR-type flip-flop SRFF1 is connected to the other input terminal of the NOR circuit NORr1 via the inverter IV2. The output terminal of the NOR circuit NORr1 is connected to the control input terminal of the transfer gate TG22. A register block BLK3 is constructed of the SR type flip-flop SRFF1, the transfer gates TG21 and TG22, the NOR circuits NORs1 and NORr1 and the inverters IV1 and IV2.

The SR-type flip-flop SRFF1 is driven by a set signal S for bringing the inside into an active state and a reset signal R for bringing the inside into an inactive state. The set signal S and the reset signal R are generated by the output signal of the preceding stage (the start ST signal for only the first stage), the output signal of the self stage and the clock signal CK. The clock signals of mutually inverted phases are inputted to the SR-type flip-flop adjacent to the SR-type flip-flop SRFF1 (CK for each odd-number flip-flop from the input side, and /CK for each even-number flip-flop).

The transfer gate TG21 is controlled to be turned on and off by a NOR signal outputted from the NOR circuit NORs1, and the clock signal CK (clock signal /CK for each even-number SR-type flip-flop SRFF1) is inputted as the set signal S to the SR-type flip-flop SRFF1 via this transfer gate TG21. On the other hand, the transfer gate TG22 is controlled to be turned on and off by the NOR signal of the NOR circuit NORr1, and the clock signal CK (clock signal /CK for each even-number SR-type flip-flop SRFF1) is inputted as the reset signal R to the SR-type flip-flop SRFF1 via this transfer gate TG22. Therefore, only when the input signal level and the output signal level of the register block BLK3 differ from each other, the transfer gates TG21 and TG22 are turned on (become conductive).

In this case, the transfer gates TG21 and TG22 are controlled by the result of logic operation of the output signal of the flip-flop of the preceding stage and the output signal of the self stage except for the SR-type flip-flop SRFF1 of the first stage, and only the SR-type flip-flop SRFF1 of the first stage is controlled by the result of logic operation of the start signal ST and the output signal of the SR-type flip-flop SRFF1. That is, the transfer gate TG21 corresponding to the set signal S is controlled by the NOR signal of the inverted input signal obtained by inverting the input signal of the register block BLK3 and the output signal, while the transfer gate TG22 corresponding to the reset signal R is controlled by the NOR signal of the input signal of the register block BLK3 and the inverted output signal obtained by inverting the output signal.

By the above operation, the clock signal CK or /CK is inputted as the set signal S only in the period during which the input signal of the register block BLK3 is in the active state and the output signal is the inactive state. The clock signal CK or /CK is inputted as the reset signal R only in the period during which the input signal of the register block BLK3 is in the inactive state and the output signal is in the active state. That is, similarly to the case of the shift register circuit constructed of the D-type flip-flops of the second embodiment, only when the input signal level and the output signal level differ from each other in each register block BLK3, the transfer gates TG21 and TG22 of the register block BLK3 are turned on (become conductive).

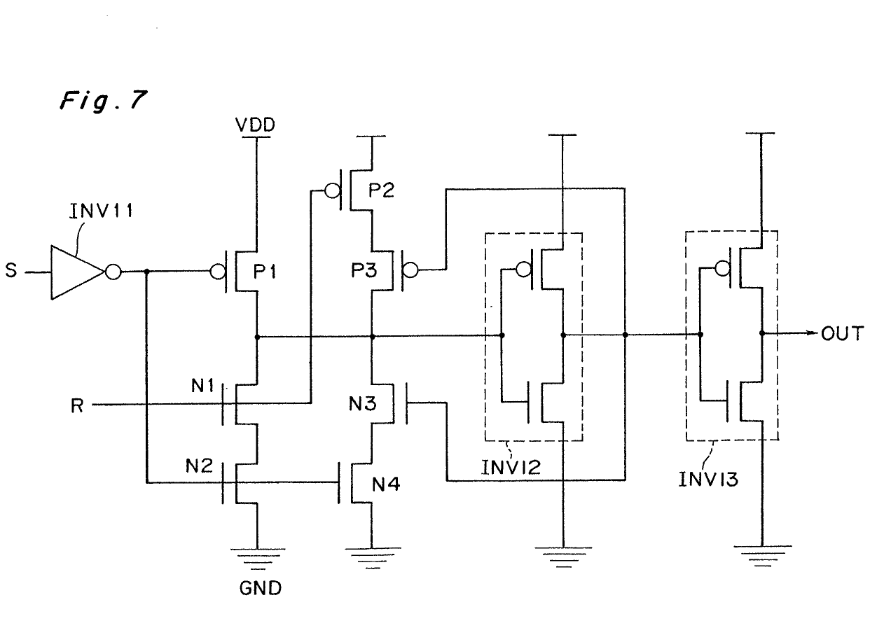

FIG. 7 shows a concrete construction of the SR-type flip-flop SRFF1 shown in FIG. 6. In this SR-type flip-flop, the set signal S is inputted to the input terminal of an inverter INV11, and the output terminal of the inverter INV11 is connected to the gate of a PMOS transistor P1. A power source VDD is connected to the source of the PMOS transistor P1, and the drain of the PMOS transistor P1 is connected to the drain of an NMOS transistor N1. A reset signal R is inputted to the gate of the NMOS transistor N1, and the source of the NMOS transistor N1 is connected to the drain of an NMOS transistor N2. The output terminal of the inverter INV11 is connected to the gate of the NMOS transistor N2, and the source of the NMOS transistor N2 is connected to a ground GND. The source of a PMOS transistor P2 to the gate of which the reset signal R is inputted is connected to the power source VDD, and the drain of the PMOS transistor P2 is connected to the source of a PMOS transistor P3. The drain of the PMOS transistor P3 is connected to the drain of the PMOS transistor P1 and to the drain of an NMOS transistor N3, and the drain of an NMOS transistor N4 is connected to the source of the NMOS transistor N3. The source of the NMOS transistor N4 is connected to the ground GND, and the output terminal of the inverter INV11 is connected to the gate of the NMOS transistor N4. The drain of the PMOS transistor P3 is connected to the input terminal of an inverter INV12, and the output terminal of the inverter INV12 is connected to the input terminal of an inverter INV13. The output terminal of the inverter INV12 is connected to the gates of the PMOS transistor P3 and the NMOS transistor N3. A signal OUT is outputted from the inverter INV13.

In the SR-type flip-flop shown in FIG. 7, the output signal OUT becomes active when the set signal S becomes active, and the output signal OUT becomes inactive when the reset signal R becomes active. If neither the set signal S nor the reset signal R is inputted (inactive), then the internal state is retained, and the output signal OUT does not change. There is also an SR-type flip-flop having a construction in which the output becomes unsettled (possibly assumes either state) when both the set signal S and the reset signals R are inputted (active). However, in the shift register circuit shown in FIG. 7, priority is given to the set state in order to avoid such an unsettled state.

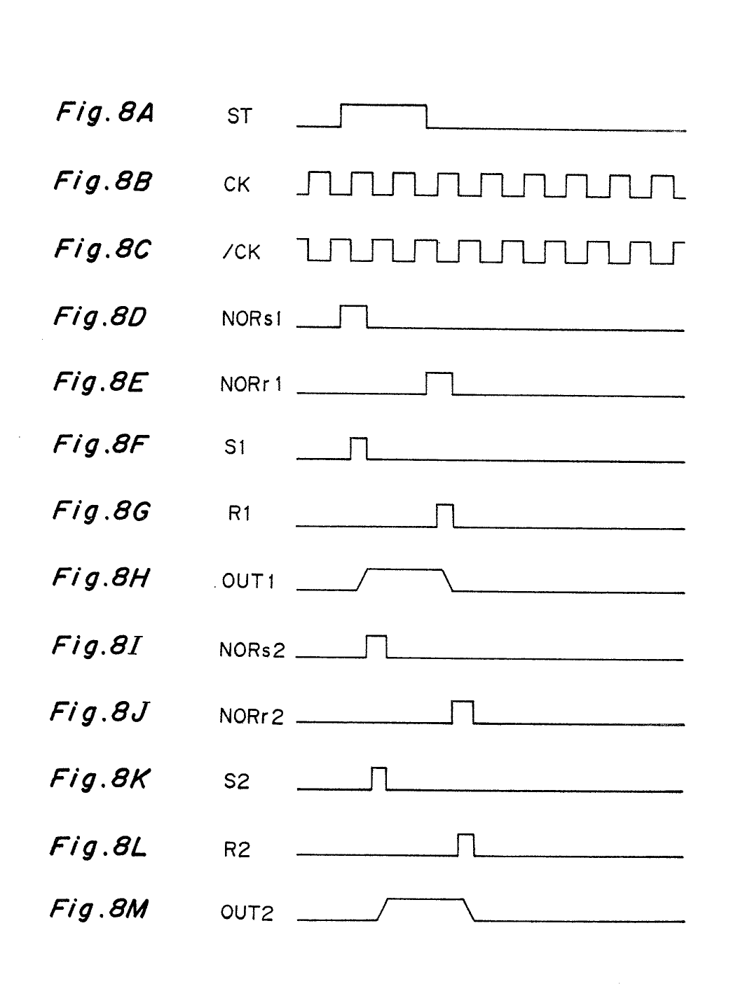

FIGS. 8A through 8M show the signal waveforms of the shift register circuit shown in FIG. 6. In FIGS. 8A through 8M, NOR signals (NORs1 and NORs2 in FIGS. 8D and 8I) that are the control signals corresponding to the set signals (S1 and S2 in FIGS. 8F and 8K) are active when the output signal level of the SR-type flip-flop SRFF1 of the stage is inactive and the output signal level of the SR-type flip-flop SRFF1 of the preceding stage (the level of the start signal ST in the first stage) is active. This indicates that the clock signal CK or /CK is inputted as the internal set signal S of each SR-type flip-flop SRFF1. NOR signals (NORr1 and NORr2 in FIGS. 8E and 8J) that are the control signals corresponding to the reset signal R are active when the output signal level of the SR-type flip-flop SRFF1 of the stage is active and the output signal level of the SR-type flip-flop SRFF1 of the preceding stage (the start signal ST in the first stage) is inactive. This indicates that the clock signal CK or /CK is inputted as the reset signal R of each flip-flop SRFF. It is to be noted that the NOR signals NORs1 and NORr1, the set signal S1, the reset signal R1 and the output signal OUT1 indicate signals relevant to the register block BLK3 of the first stage, while the NOR signals NORs2 and NORr2, the set signal S2, the reset signal R2 and the output signal OUT2 indicate signals relevant to the register block BLK3 of the second stage. Although the signal waveforms of the register block BLK3 of the third and subsequent stages are not shown, the same thing as described above can be said.

Although the NOR circuits NORs1 and NORr1 are employed as the first and second logic operation sections whose outputs are the inverted outputs in the third embodiment, it is acceptable to employ an OR circuit whose output is not inverted by the control input conditions and the like of the transfer gate. The first and second logic operation sections can also be constructed by combining other logic operators.

(Fourth Embodiment)

If the clock input terminal of each flip-flop is connected as only a transfer gate in the constructions of the second and third embodiments of FIG. 3 and FIG. 6, then the clock input terminal of each flip-flop is put in a floating state when the transfer gate is in the OFF-state. In the above case, if the potential level of the clock input terminal is shifted in the undesirable direction due to an external noise or an internal leak current, then the shift register circuit will malfunction. In this case, the possibility of the occurrence of malfunction is reduced since the period during which the floating state is present becomes short when the operation frequency of the shift register circuit is high. The possibility of the occurrence of malfunction is also similarly reduced since the potential level is relatively stable when the internal parasitic capacitance is sufficiently large. Accordingly, it is also effective to intentionally add a capacitance to the clock input terminal. However, it is preferable to adopt another stabilizing means since the addition of a capacitance becomes a load of circuit operation.

In order to prevent the possible occurrence of the malfunction as described above, it is preferable to set the clock input terminal of the flip-flop to a level at which the flip-flop is brought into a latched state when the transfer gate is in the OFF-state.

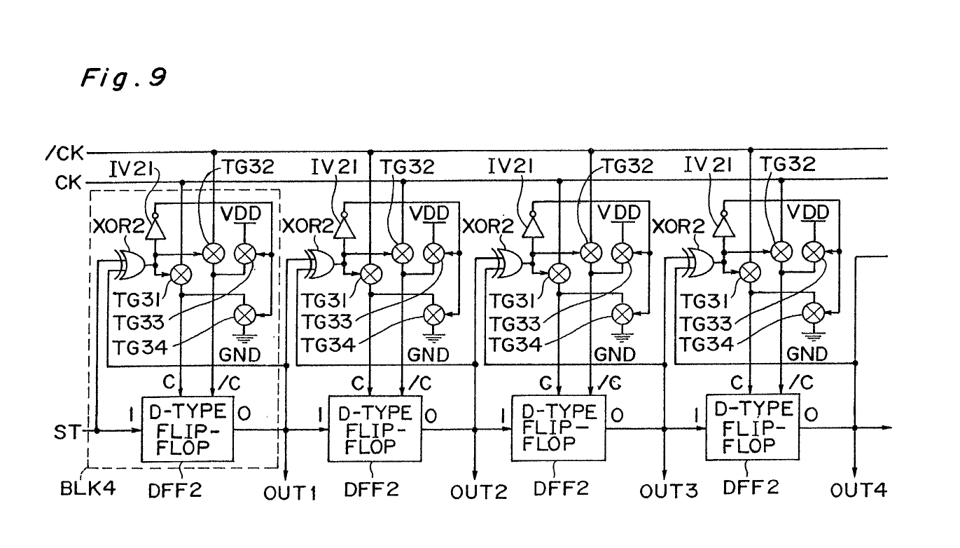

FIG. 9 shows the construction of a shift register circuit in which the flip-flop is brought into the latched state when the transfer gate of the fourth embodiment of the present invention is in the OFF-state. FIG. 9 shows the construction of a shift register circuit that employs D-type flip-flops, and the same thing can be said for a construction that employs SR-type flip-flops.

As shown in FIG. 9, there are provided a plurality of serially connected D-type flip-flops DFF2 (only four are shown in FIG. 9 for the sake of simplicity), transfer gates TG31 and TG32 provided for each D-type flip-flop DFF2 and an exclusive-OR circuit XOR2 that serves as a logic operation section provided for each D-type flip-flop DFF2. The input terminal of the D-type flip-flop DFF2 is connected to one input terminal of the exclusive-OR circuit XOR2, and the output terminal of the D-type flip-flop DFF2 is connected to the other input terminal of the exclusive-OR circuit XOR2. The output terminal of the exclusive-OR circuit XOR2 is connected to the control input terminals of the transfer gates TG31 and TG32. The transfer gate TG31 is controlled to be turned on and off by the exclusive-OR signal of the exclusive-OR circuit XOR2, and the clock signal CK (clock signal /CK for each even-number D-type flip-flop DFF2) is inputted to the D-type flip-flop DFF2 via this transfer gate TG31. The transfer gate TG32 is controlled to be turned on and off by the exclusive-OR signal outputted from the exclusive-OR circuit XOR2, and the clock signal /CK (clock signal CK for each even-number D-type flip-flop DFF2) is inputted to the D-type flip-flop DFF2 via this transfer gate TG32. Therefore, only when the input signal level and the output signal level of the D-type flip-flop DFF2 differ from each other, the transfer gates TG31 and TG32 are turned on (become conductive).

Although the exclusive-OR circuit XOR2 is employed as the logic operation section in the fourth embodiment, the logic operation section can also be provided by combining other logic operators.

One terminal of a transfer gate TG33 that serves as a retainment signal circuit is connected between the transfer gate TG32 and the D-type flip-flop DFF2, and the power source VDD is connected to the other terminal of the transfer gate TG33. One terminal of a transfer gate TG34 that serves as a retainment signal circuit is connected between the transfer gate TG31 and the D-type flip-flop DFF2, and the ground GND is connected to the other terminal of the transfer gate TG34. The transfer gates TG33 and TG34 are controlled to be turned on and off by the output signal of an inverter IV21 whose input terminal is connected to the output terminal of the exclusive-OR circuit XOR2.

A register block BLK4 is constructed of the D-type flip-flop DFF2, the transfer gates TG31, TG32, TG33 and TG34, the exclusive-OR circuit XOR2 and the inverter IV21.

In the D-type flip-flop DFF2, the transfer gates TG31 and TG32 for inputting the clock signals into the D-type flip-flops DFF2 are controlled by an exclusive-OR signal similarly to the D-type flip-flop DFF1 of FIG. 3. Further, retainment signals respectively having the power source level and the ground level are inputted to the clock input terminals of the D-type flip-flop DFF2 by the transfer gates TG33 and TG34 of the subsequent stages (located on the flip-flop side) of the transfer gates TG31 and TG32. The clock input terminal C (clock signal corresponding to signal transfer) of the D-type flip-flop DFF2 comes to have the ground level when the transfer gate TG31 of the clock signal is off (non-conductive), and the clock input terminal /C of the D-type flip-flop DFF2 (clock signal corresponding to signal latching) comes to have the power source level when the transfer gate TG32 of the clock signal is off (non-conductive). By the above operation, the retainment signals for retaining the internal state are to be inputted to each D-type flip-flop DFF2 in a period during which the clock signal is not inputted to the D-type flip-flop DFF2, and therefore, the stability of operation can be secured.

(Fifth Embodiment)

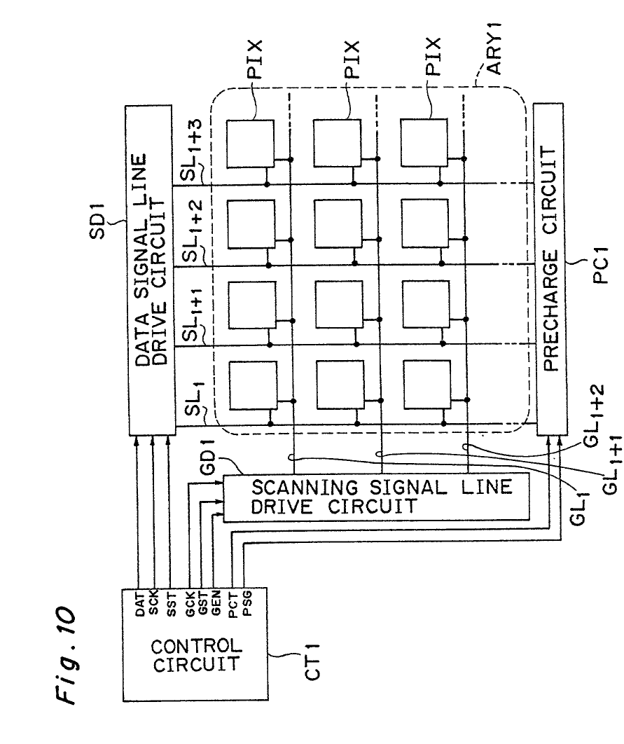

FIG. 10 is a block diagram showing the construction of the image display device of the fifth embodiment of the present invention.

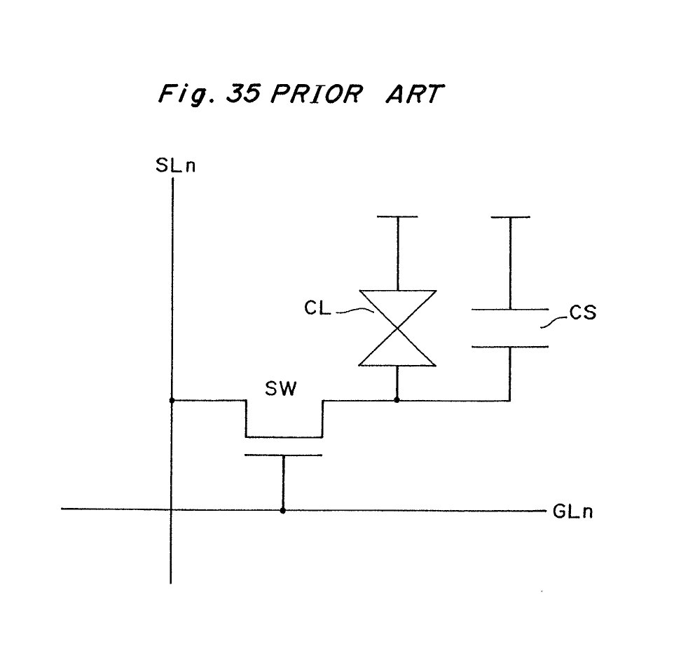

In FIG. 10, the image display device is constructed of a pixel array ARY1, a data signal line drive circuit SD1, a scanning signal line drive circuit GD1, a precharge circuit PC1, a control circuit CT1 and so on. The data signal line drive circuit SD1, the scanning signal line drive circuit GD1 and the precharge circuit PC1 are driven by signals generated in the control circuit CT1. The internal construction of the pixel PIX of this image display device is the same as that of the pixel PIX of FIG. 35.

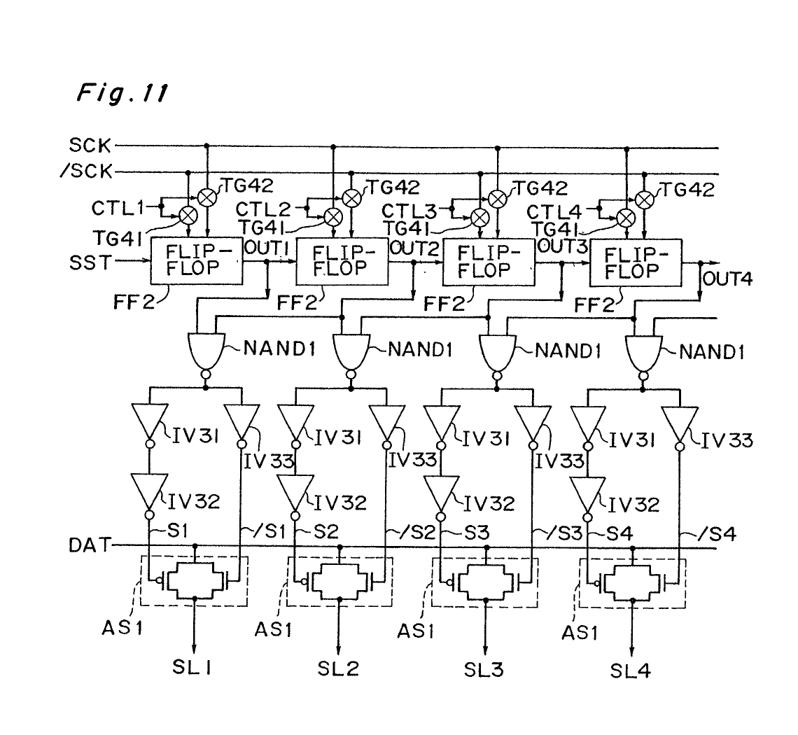

FIG. 11 shows the construction of the data signal line drive circuit SD1. As shown in FIG. 11, the shift register circuit of the data signal line drive circuit has a plurality of serially connected flip-flops FF2 and transfer gates TG41 and TG42 provided for each flip-flop FF2. The output terminal of the flip-flop FF2 is connected to one input terminal of a NAND circuit NAND1, and the output terminal of the flip-flop FF2 of the subsequent stage is connected to the other input terminal of the NAND circuit NAND1. The output terminal of the NAND circuit NAND1 is connected to one control input terminal of an analog switch AS1 via serially connected inverters IV31 and IV32, and the output terminal of the NAND circuit NAND1 is connected to the other control input terminal of the analog switch AS1 via an inverter IV33. A video signal DAT is inputted to the input terminal of the analog switch AS1, and the analog switch AS1 is turned on and off by control inputs (S1 through S4, and /S1 through /S4 in FIG. 11), and the video signal DAT is outputted to data signal lines (SL1 through SL4 in FIG. 11).

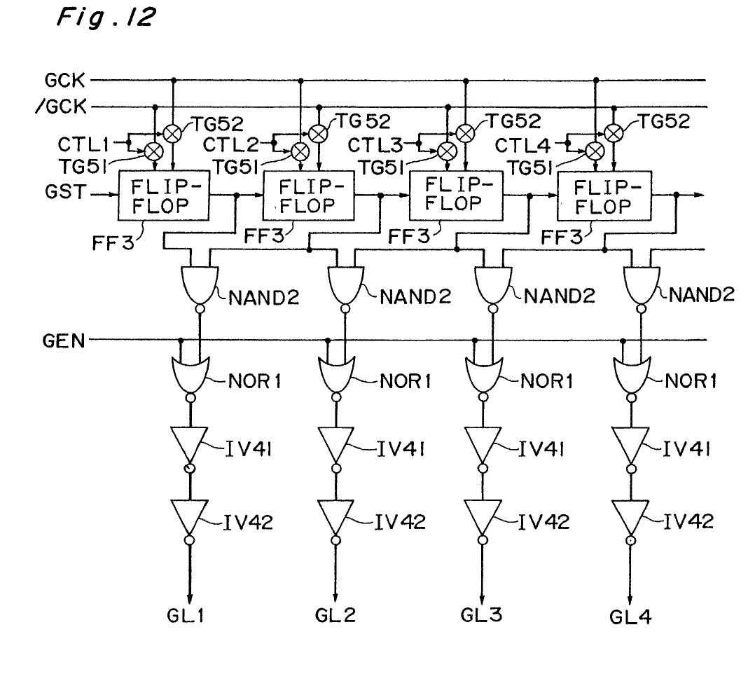

FIG. 12 shows the construction of the scanning signal line drive circuit GD1. As shown in FIG. 12, the shift register circuit of the scanning signal line drive circuit has a plurality of serially connected flip-flops FF3 and transfer gates TG51 and TG52 provided for each flip-flop FF3. The output terminal of the flip-flop FF3 is connected to one input terminal of a NAND circuit NAND2, and the output terminal of the flip-flop FF3 of the subsequent stage is connected to the other input terminal of the NAND circuit NAND2. The output terminal of the NAND circuit NAND2 is connected to one input terminal of a NOR circuit NOR1, and an enable signal GEN is inputted to the other input terminal of the NOR circuit NOR1. The input terminal of an inverter IV41 is connected to the output terminal of the NOR circuit NOR1, and the output terminal of the inverter IV41 is connected to the input terminal of an inverter IV42. A scanning signal is outputted to scanning signal lines (GL1 through GL4 in FIG. 12) from the inverter IV42.

In this case, the capacitive loads of the signal lines of clock signals SCK, /SCK, GCK and /GCK are reduced by employing the shift register circuit shown in the second embodiment for the data signal line drive circuit SD1 or the scanning signal line drive circuit GD1, and therefore, consumption power reduction and cost reduction can be achieved.

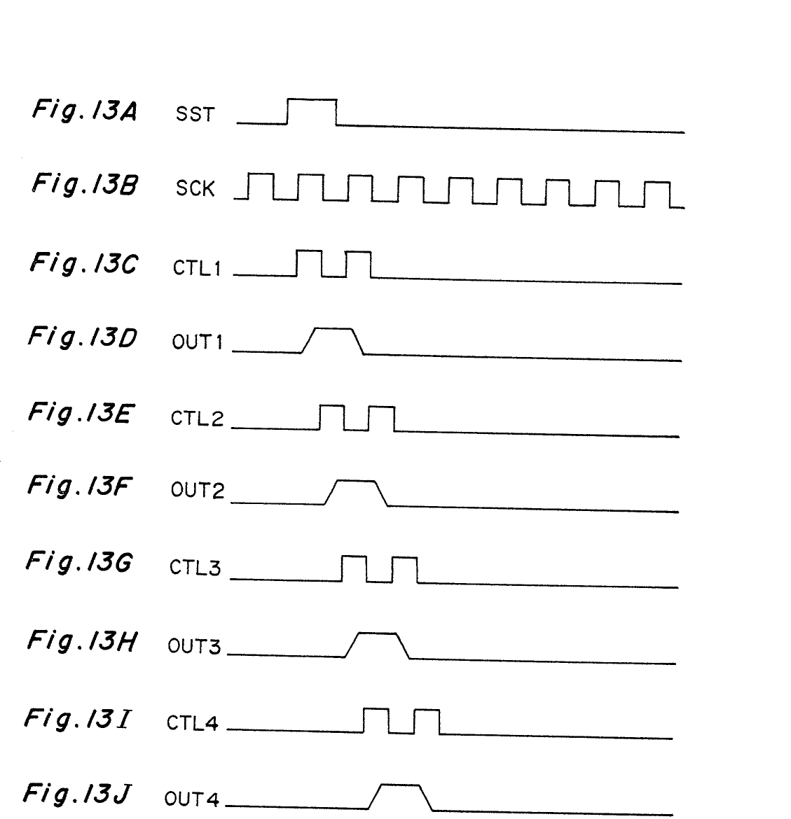

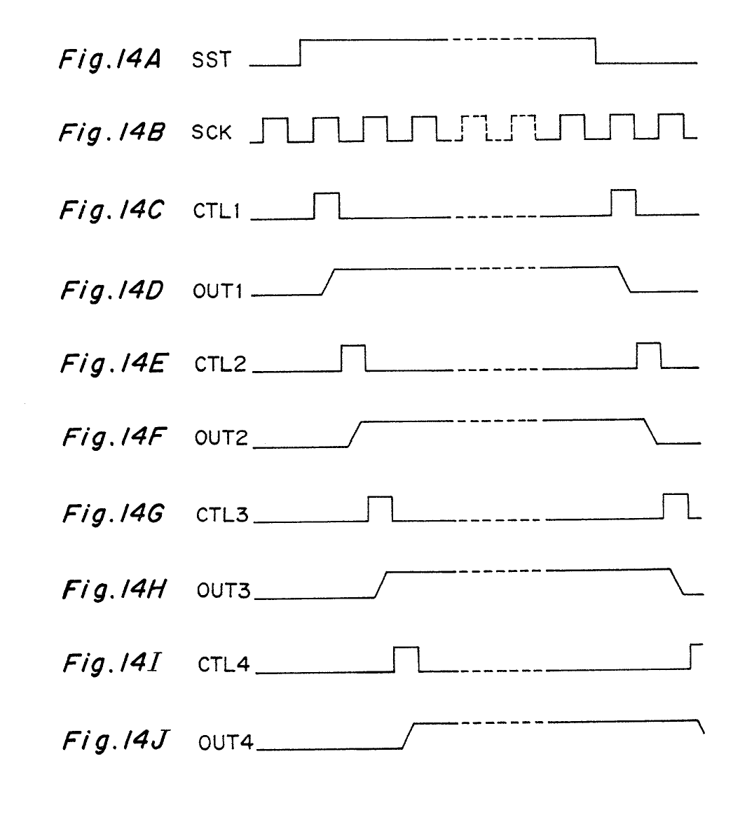

FIGS. 13A through 13J and FIGS. 14A through 14J are charts showing the internal signal waveforms of the data signal line drive circuit shown in FIG. 11.

In contrast to the fact that the width of a pulse to be transferred through the shift register circuit is the minimum (corresponding to one cycle of a clock signal SCK) in FIGS. 13A through 13J, the pulse width is widened in FIGS. 14A through 14J. However, in spite of the difference in pulse width, the period during which the control signal of the transfer gate is active (period during which the clock signal is inputted) is same. That is, the loads of the clock signal line can be restrained to the minimum (two or less) for whatever pulse width.

For example, the following two points can herein be enumerated as the merits of changing the pulse width.

One point is to optimize the width of a sampling pulse (pulse for writing image data into the data signal line) of the data signal line drive circuit. If the width of the sampling pulse is narrow, then the video signal cannot sufficiently be written into the data signal line, degrading the display quality. However, if the sampling pulse width is made excessively long, then the load of the video signal line becomes heavy, possibly causing an increase in the load of an external IC (video amplifier or the like). Therefore, it is preferable to adopt the optimum sampling pulse according to the specifications (display size, resolution, driving frequency, driving voltage and so on) of the image display device. In the construction of this data signal line drive circuit, the loads of the clock signal line can sufficiently be reduced with respect to the sampling pulse width optimized as above.

The other point is the writing of the side black (black display regions at the top and bottom of the video region) in a wide screen display mode. The writing of the side black video signal (black signal), which can also be executed by means of the data signal line drive circuit, is required to be executed in the vertical retrace line interval, and the time of the interval is insufficient if the driving speed is the same as that of normal image display. Therefore, it is required to collectively write the video signal (side black signal) instead of writing the signal every data signal line. For this purpose, the outputs of the flip-flops constituting the shift register circuit are required to be all activated by sufficiently increasing the width of the pulse to be transferred inside the shift register circuit. According to the construction of this data signal line drive circuit, the loads of the clock signal line can sufficiently be reduced even when the pulse width is extremely long like this.

(Sixth Embodiment)

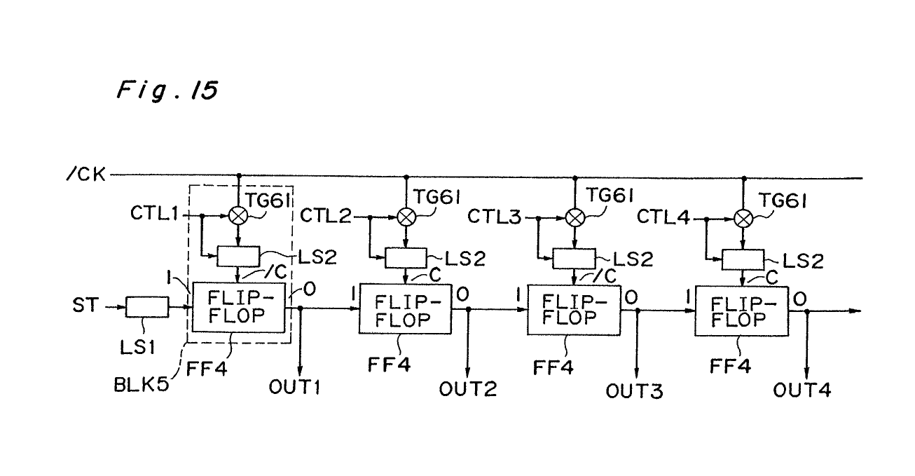

FIG. 15 is a block diagram showing the construction of the shift register circuit of the sixth embodiment of the present invention. This shift register circuit has the same construction as that of the first embodiment except for the level shift circuit. In FIG. 15, this shift register circuit has a plurality of serially connected flip-flops FF4, a transfer gate TG61 provided for each flip-flops FF4, a level shift circuit LS1 the input terminal of which receives the start signal ST and the output terminal of which is connected to the input terminal of the flip-flop FF4 of the first stage and a level shift circuit LS2 provided for each flip-flop FF4. The clock signal /CK is inputted to the level shift circuit LS2 via the transfer gate TG61 that is controlled to be turned on and off by control signals (CTL1 through CTL4 in FIG. 15), has its signal level shifted (expanded in amplitude) in the level shift circuit LS2 whose operation is controlled by the control signals and is thereafter inputted to the flip-flop FF4. A register block BLK5 is constructed of the flip-flop FF4, the transfer gate TG61 and the level shift circuit LS2.

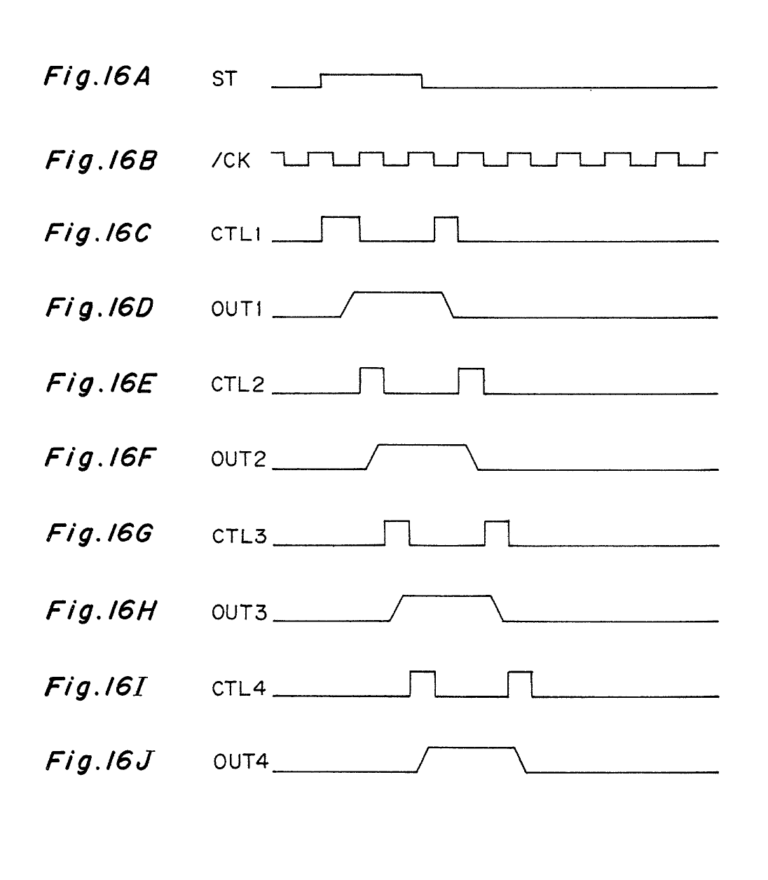

FIGS. 16A through 16J show the signal waveforms of the above-mentioned shift register circuit. As shown in FIGS. 16A through 16J, the control signals (CTL1 through CTL4 in FIGS. 16C, 16E, 16G and 16I) are set so as to become active only when the internal state of the corresponding flip-flop FF4 (output signals OUT1 through OUT4 in FIGS. 16D, 16F, 16H and 16J) changes. Therefore, the clock signal /CK is expanded in amplitude only when the output signals (OUT1 through OUT4 in FIGS. 16D, 16F, 16H and 16J) of the corresponding flip-flop FF4 change and then inputted to the flip-flop FF4.

The flip-flop FF4 operates normally when the clock signal is supplied at least only in accordance with the timing at which the internal state changes. Therefore, the control signals shown in FIGS. 16C, 16E, 16G and 16I are sufficient. With this arrangement, the period during which the clock signal is inputted can be reduced, and therefore, the loads of the clock signal line can be restrained to the minimum.

Furthermore, the period during which the level shift circuit LS2 operates can also be shortened, and therefore, the consumption of power of the level shift circuit LS2 can be restrained to the minimum. If, in particular, a stationary current flow type is adopted as a level shift circuit for the achievement of operation even with degraded transistor characteristics (large threshold voltage, small mobility, long channel length, and so on), the effect of reducing the consumption of current becomes very great.

The control signals in FIGS. 16C, 16E, 16G and 16J become active only in the period during which the input signal level and the output signal level of the flip-flop FF4 (shown in FIG. 15) differ from each other.

The internal state of the flip-flop FF4 changes in the shift register circuit when the input signal level and the output signal level of the flip-flop differ from each other. Therefore, by detecting whether the input signal level and the output signal level of the flip-flop differ from each other and using the result as a control signal, the capacitive load of the clock signal line can be reduced with a simple construction and the load of the external circuit can be reduced, allowing the provision of a shift register circuit capable of reducing the loads of the external circuit and achieving consumption power reduction and cost reduction.

(Seventh Embodiment)

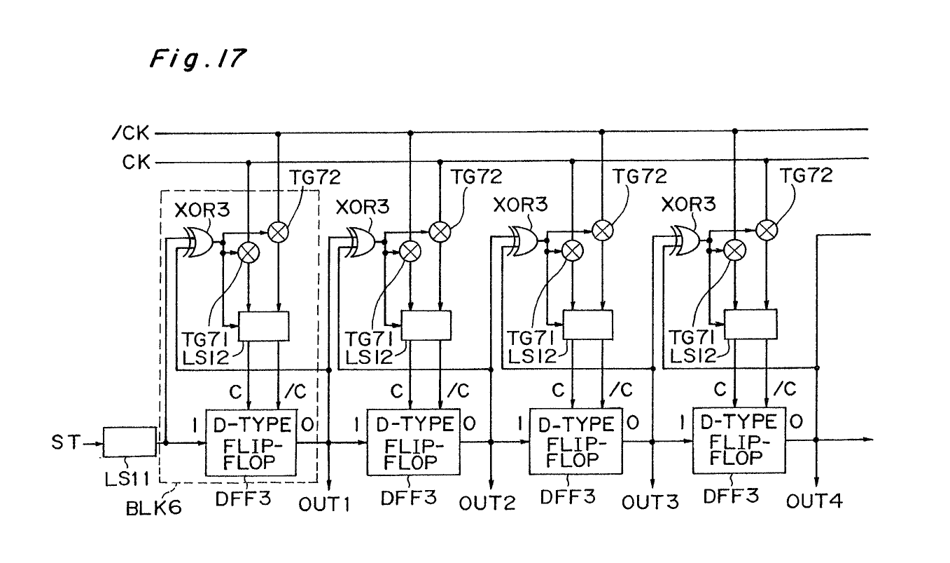

FIG. 17 is a block diagram showing the construction of the shift register circuit of the seventh embodiment of the present invention. This shift register circuit has the same construction as that of the shift register circuit of the second embodiment shown in FIG. 3 except for the level shift circuit.

As shown in FIG. 17, this shift register circuit has a plurality of serially connected D-type flip-flops DFF3 (only four are shown in FIG. 17 for the sake of simplicity), transfer gates TG71 and TG72 provided for each D-type flip-flop DFF3, a level shift circuit LS11 the input terminal of which receives the start signal ST and the output terminal of which is connected to the input terminal of the D-type flip-flop DFF3 of the first stage, a level shift circuit LS12 provided for each D-type flip-flop DFF3 and an exclusive-OR circuit XOR3 that serves as a logic operation section provided for each D-type flip-flop DFF3. The input terminal of the D-type flip-flop DFF3 is connected to one input terminal of the exclusive-OR circuit XOR3, the output terminal of the D-type flip-flop DFF3 is connected to the other input terminal of the exclusive-OR circuit XOR3, and the output terminal of the exclusive-OR circuit XOR3 is connected to the control input terminals of the transfer gates TG71 and TG72. A register block BLK6 is constructed of the D-type flip-flop DFF3, the transfer gates TG71 and TG72, the exclusive-OR circuit XOR3 and the level shift circuit LS12.

Although the exclusive-OR circuit XOR3 is employed as the logic operation section in the seventh embodiment, the logic operation section can also be provided by combining other logic operators.

The transfer gate TG71 is controlled to be turned on and off by an exclusive-OR signal outputted from the exclusive-OR circuit XOR3, and a clock signal CK (clock signal /CK for each even-number register block BLK6) is inputted to the level shift circuit LS12 via this transfer gate TG71. The clock signal CK (clock signal /CK for each even-number register block BLK6) shifted in level (expanded in amplitude) by the level shift circuit LS12 is inputted to the D-type flip-flop DFF3. On the other hand, the transfer gate TG72 is controlled to be turned on and off by an exclusive-OR signal outputted from the exclusive-OR circuit XOR3, and the clock signal /CK (clock signal CK for each even-number register block BLK6) is inputted to the level shift circuit LS12 via this transfer gate TG72. The clock signal /CK (clock signal CK for each even-number register block BLK6) shifted in level (expanded in amplitude) by the level shift circuit LS12 is inputted to the D-type flip-flop DFF3.

In the shift register circuit having the above-mentioned construction, the transfer gates TG71 and TG72 are turned on (become conductive) and the level shift circuit LS12 is brought into the operating state only when the input signal level and the output signal level of the D-type flip-flop DFF3 differ from each other.

A concrete construction of the D-type flip-flop DFF3 is the same as the construction of the D-type flip-flop DFF3 of the second embodiment shown in FIG. 4. In this D-type flip-flop, an input signal IN is transferred as an output signal to the D-type flip-flop DFF3 of the next stage when the clock signals CK and /CK are active. The internal state is retained and the output signal does not change when the clock signals CK and /CK are inactive.

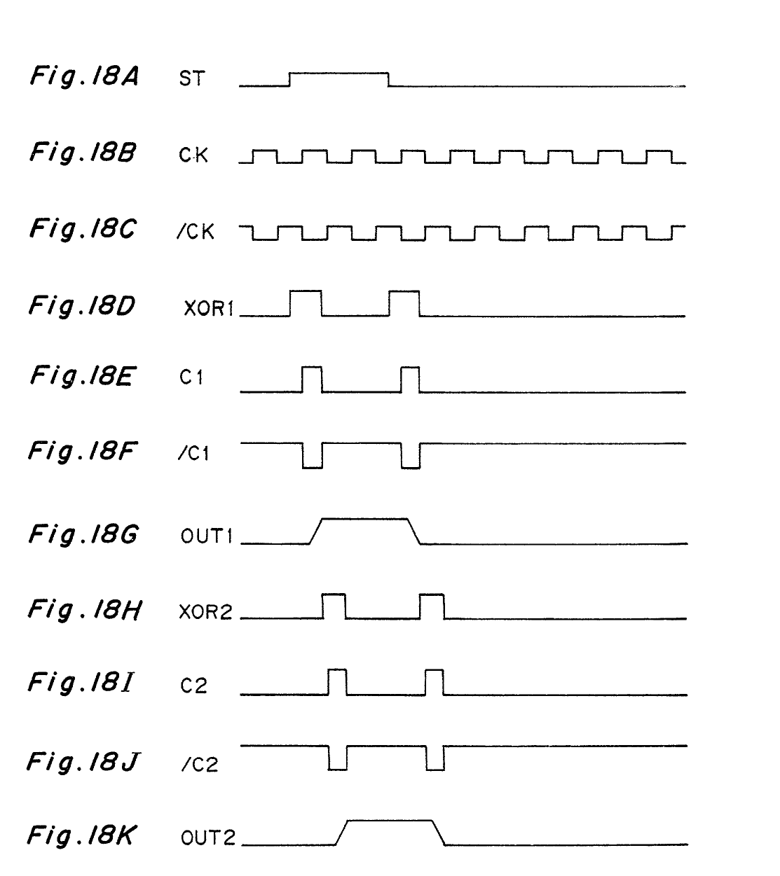

FIGS. 18A through 18K show the signal waveforms of the shift register circuit shown in FIG. 17. In FIGS. 18A through 18K, exclusive-OR signals (XOR1 and XOR2 in FIGS. 18D and 18H) that serve as control signals become active when the input signal level and the output signal level of the register block BLK6 differ from each other. This indicates that the internal clock signals C and /C of each flip-flop DFF3 (shown in FIG. 17) are inputted only in the period during which the exclusive-OR signal is active. It is to be noted that the exclusive-OR signal XOR1, the internal clock signals C1 and /C1 and the output signal OUT1 show signals relevant to the register block BLK6 of the first stage, while the exclusive-OR signal XOR2, the internal clock signals C2 and /C2 and the output signal OUT2 show signals relevant to the register block BLK6 of the second stage. Although the signal waveforms relevant to the register blocks BLK6 of the third and subsequent stages are not shown in the figures, the same thing as described above can be said.

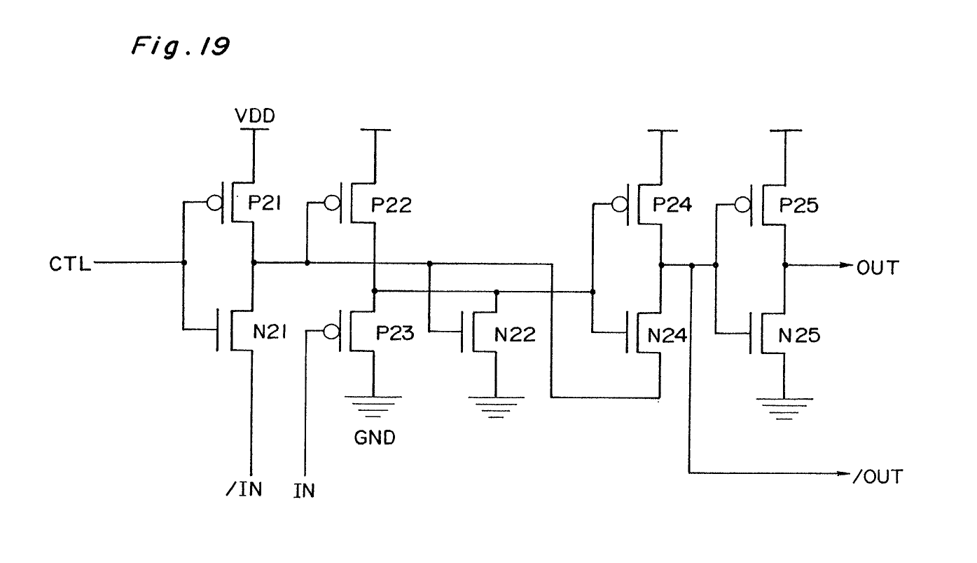

FIG. 19 shows the circuit diagram of a level shift circuit employed in the shift register circuit shown in FIG. 17. As shown in FIG. 19, a control signal CTL is inputted to the gate of a PMOS transistor P21, and a power source VDD is connected to the source of the PMOS transistor P21. The drain of an NMOS transistor N21 is connected to the drain of the PMOS transistor P21, a control signal CTL is inputted to the gate of the NMOS transistor N21, and an input signal /IN is inputted to the source of the NMOS transistor N21. The gate of a PMOS transistor P22 is connected to the drain of the PMOS transistor P21, and the power source VDD is connected to the source of the PMOS transistor P22. The source of a PMOS transistor P23 is connected to the drain of the PMOS transistor P22, the drain of the PMOS transistor P23 is connected to the ground GND, and an input signal IN is inputted to the gate of the PMOS transistor P23. The drain of the NMOS transistor N22 is connected to the source of the PMOS transistor P23, and the ground GND is connected to the source of the NMOS transistor N22. The gate of the NMOS transistor N22 is connected to the drain of the PMOS transistor P21. Further, the gate of a PMOS transistor P24 is connected to the drain of the NMOS transistor N22, and the power source VDD is connected to the source of the PMOS transistor P24. The drain of an NMOS transistor N24 is connected to the drain of the PMOS transistor P24, the gate of the NMOS transistor N24 is connected to the drain of the NMOS transistor N22, and the source of the NMOS transistor N24 is connected to the drain of the PMOS transistor P21. The drain of the PMOS transistor P24 is connected to the gate of a PMOS transistor P25, and the source of the PMOS transistor P25 is connected to the power source VDD. The drain of the PMOS transistor P25 is connected to the drain of an NMOS transistor N25, the source of the NMOS transistor N25 is connected to the ground GND, and the gate of the NMOS transistor N25 is connected to the drain of the PMOS transistor P24. An output signal OUT is outputted from the drain of the PMOS transistor P25, and an output signal /OUT is outputted from the drain of the PMOS transistor P24.

The terminals CTL, IN, /IN, OUT and /OUT of the level shift circuit correspond to a control input terminal located on the left-hand side, an input terminal located on the upper left-hand side, an input terminal located on the upper right-hand side, an output terminal located on the lower left-hand side and an output terminal located on the lower right-hand side, respectively, of the level shift circuit LS12 shown in FIG. 17.

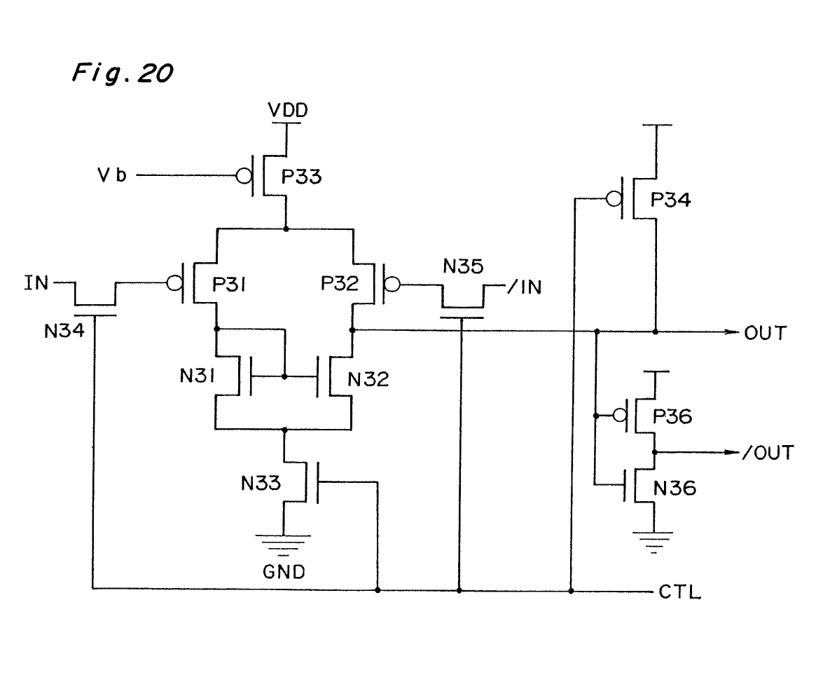

FIG. 20 shows the circuit diagram of another level shift circuit employed in the shift register circuit shown in FIG. 17. As shown in FIG. 20, this level shift circuit receives an input signal IN to the gate of a PMOS transistor P31 via an NMOS transistor N34, and the drain of a PMOS transistor P33 is connected to the source of the PMOS transistor P31. A power source VDD is connected to the source of the PMOS transistor P33, and a signal Vb from a fixed bias source (not shown) is inputted to the gate of the PMOS transistor P33. The source of a PMOS transistor P32 is connected to the source of the PMOS transistor P31. The drain of an NMOS transistor N31 is connected to the drain of the PMOS transistor P31, and the source of the NMOS transistor N31 is connected to the drain of an NMOS transistor N33. On the other hand, the drain of an NMOS transistor N32 is connected to the drain of the PMOS transistor P32, and the source of the NMOS transistor N32 is connected to the drain of the NMOS transistor N33. The source of the NMOS transistor N33 is connected to the ground GND. The gate and drain of the NMOS transistor N31 are connected together, and the gates of the NMOS transistors N31 and N32 are connected together. Further, an input signal IIN is inputted to the gate of the PMOS transistor P32 via an NMOS transistor N35. A control signal CTL is inputted to the gates of the NMOS transistors N33, N34 and N35. The drain of the PMOS transistor P32 is connected to the drain of a PMOS transistor P34, the power source VDD is connected to the source of the PMOS transistor P34, and a control signal CTL is inputted to the gate of a PMOS transistor P34. An output signal OUT is outputted from the drain of the PMOS transistor P32. The drain of the PMOS transistor P32 is connected to the gate of a PMOS transistor P36, and the source of the PMOS transistor P36 is connected to the power source VDD. The drain of the PMOS transistor P36 is connected to the drain of an NMOS transistor N36, the gate of the NMOS transistor N36 is connected to the gate of the PMOS transistor P36, and the source of the NMOS transistor N36 is connected to the ground GND. An output signal /OUT is outputted from the drain of the PMOS transistor P36.

The terminals CTL, IN, /IN, OUT and /OUT of the level shift circuit correspond to a control input terminal located on the left-hand side, an input terminal located on t he upper left-hand side, an input terminal located on the upper right-hand side, an output terminal located on the lower left-hand side and an output terminal located on the lower right-hand side, respectively, of the level shift circuit LS12 shown in FIG. 17.

As described above, the transfer gates TG71 and TG72 can be made active (brought into the ON-state) when the input signal level and the output signal level of the register block BLK6 differ from each other with a simple construction employing the exclusive-OR circuit XOR3. In the D-type flip-flop DFF3, to which the clock signal is supplied only in the timing at which the internal state changes, allows the shortening of the period during which the clock signal is inputted and allows the loads of the clock signal line to be restrained to the minimum.

Furthermore, the period during which the level shift circuit LS12 operates can also be shortened, and therefore, the consumption of power of the level shift circuit LS12 can be restrained to the minimum.

(Eighth Embodiment)

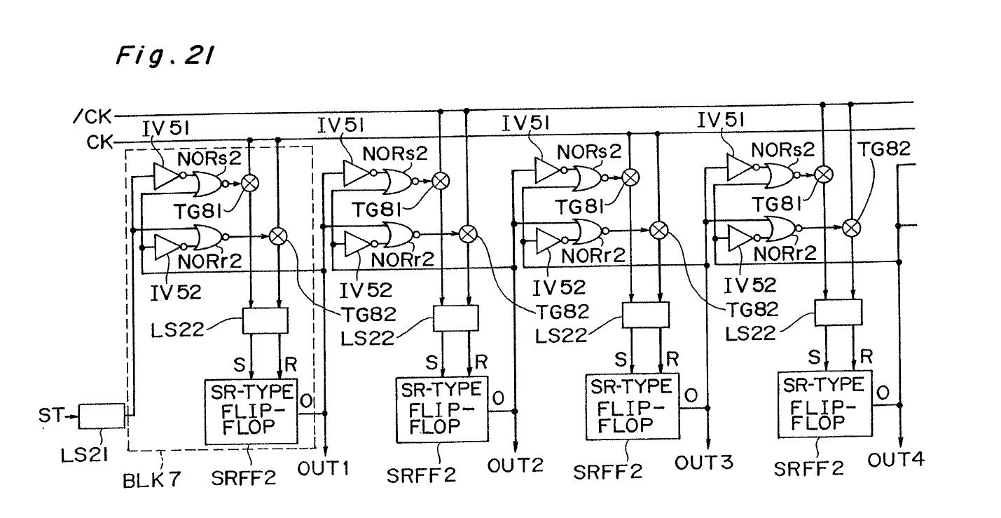

FIG. 21 is a block diagram showing the construction of the shift register circuit of the eighth embodiment of the present invention. This shift register circuit has the same construction as that of the shift register circuit of the third embodiment shown in FIG. 6 except for the level shift circuit.

As shown in FIG. 21, there are provided a plurality of serially connected SR-type flip-flops SRFF2 (only four are shown in FIG. 21 for the sake of simplicity), transfer gates TG81 and TG82 provided for each SR-type flip-flop SRFF2, a NOR circuit NORs2 that serves as a first logic operation section provided for each SR-type flip-flop SRFF2, a NOR circuit NORr2 that serves as a second logic operation section provided for each SR-type flip-flop SRFF2, inverters IV51 and IV52, a level shift circuit LS21 for shifting the level of a start signal ST and a level shift circuit LS22 provided for each SR-type flip-flop SRFF2. An output signal (start signal ST for only the SR-type flip-flop SRFF2 of the first stage) of the SR-type flip-flop SRFF2 of the preceding stage is inputted to one input terminal of the NOR circuit NORs2 via the inverter IV51, and the output terminal of the SR-type flip-flop SRFF2 is connected to the other input terminal of the NOR circuit NORs2. The output terminal of the NOR circuit NORs2 is connected to the control input terminal of a transfer gate TG81. An output signal (start signal ST for only the SR-type flip-flop SRFF2 of the first stage) of the SR-type flip-flop SRFF2 of the preceding stage is inputted to one input terminal of the NOR circuit NORr2, and the output terminal of the SR-type flip-flop SRFF2 is connected to the other input terminal of the NOR circuit NORr2 via the inverter IV52. The output terminal of the NOR circuit NORr2 is connected to the control input terminal of a transfer gate TG82.

A register block BLK7 is constructed of the SR-type flip-flop SRFF2, the transfer gates TG81 and TG82, the NOR circuits NORs2 and NORr2, the inverters IV51 and IV52 and the level shift circuit LS22.

The transfer gate TG81 is controlled to be turned on and off by a NOR signal outputted from the NOR circuit NORs2, and a clock signal CK (clock signal /CK for each even-number register block BLK7) is inputted to a level shift circuit LS22 via this transfer gate TG81. A clock signal CK (clock signal /CK for each even-number register block BLK7) shifted in level (expanded in amplitude) by the level shift circuit LS22 is inputted to the set terminal of the SR-type flip-flop SRFF2. On the other hand, the transfer gate TG82 is controlled to be turned on and off by a NOR signal outputted from the NOR circuit NORr2, and the clock signal CK (clock signal /CK for each even-number register block BLK7) is inputted to the level shift circuit LS22 via this transfer gate TG82. The clock signal CK (clock signal /CK for each even-number register block BLK7) shifted in level (expanded in amplitude) by the level shift circuit LS22 is inputted to the reset terminal of the SR-type flip-flop SRFF2.

In the shift register circuit having the above-mentioned construction, the clock signal CK (clock signal /CK for each even-number register block BLK7) is inputted to the level shift circuit LS22 via the transfer gates TG81 and TG82, expanded in amplitude by the level shift circuit LS22 and thereafter inputted as a set signal S and a reset signal R to each SR-type flip-flop SRFF2. In this case, the transfer gates TG81 and TG82 and the level shift circuit LS22 are controlled by a level operation result of the input signal and the output signal of the register block BLK7. That is, a control signal for the transfer gate TG81 corresponding to the set signal S is controlled by a NOR signal of an inverted input signal obtained by inverting the input signal of the register block BLK7 and the output signal of the register block BLK7. On the other hand, a control signal for the transfer gate TG82 corresponding to the reset signal R is controlled by a NOR signal of the input signal of the register block BLK7 and an inverted output signal obtained by inverting the output signal of the register block BLK7. By the above operation, the clock signal CK (clock signal /CK for each even-number register block BLK7) is inputted as the set signal S only in the period during which the SR-type flip-flop SRFF2 of the stage is in the inactive state and the SR-type flip-flop SRFF2 of the preceding stage is in the active state (the start signal ST is active only in the SR-type flip-flop SRFF2 of the first stage). The clock signal CK (clock signal /CK for each even-number register block BLK7) is inputted as the reset signal R only in the period during which the SR-type flip-flop SRFF2 of the stage is in the active state and the SR-type flip-flop SRFF2 of the preceding stage is in the inactive state (the start signal ST is inactive only in the SR-type flip-flop SRFF2 of the first stage). That is, similarly to the case of the shift register circuit constructed of the D-type flip-flops, the transfer gates TG81 and TG82 are turned on (become conductive) only when the input signal level and the output signal level of the register block BLK7 differ from each other.

The SR-type flip-flop SRFF2 has the same construction as that of the SR-type flip-flop of the third embodiment shown in FIG. 7. In this SR-type flip-flop, the output signal OUT becomes active when the set signal S becomes active, and the output signal OUT becomes inactive when the reset signal R becomes active. The internal state is retained and the output signal OUT does not change when neither the set signal S nor the reset signals R is inputted (inactive). There is also an SR-type flip-flop having a construction in which the output becomes unsettled (possibly assumes either state) when both the set signal S and the reset signals R are inputted (active). However, in the SR-type flip-flop SRFF2 shown in FIG. 21, priority is given to the set state in order to avoid such an unsettled state.

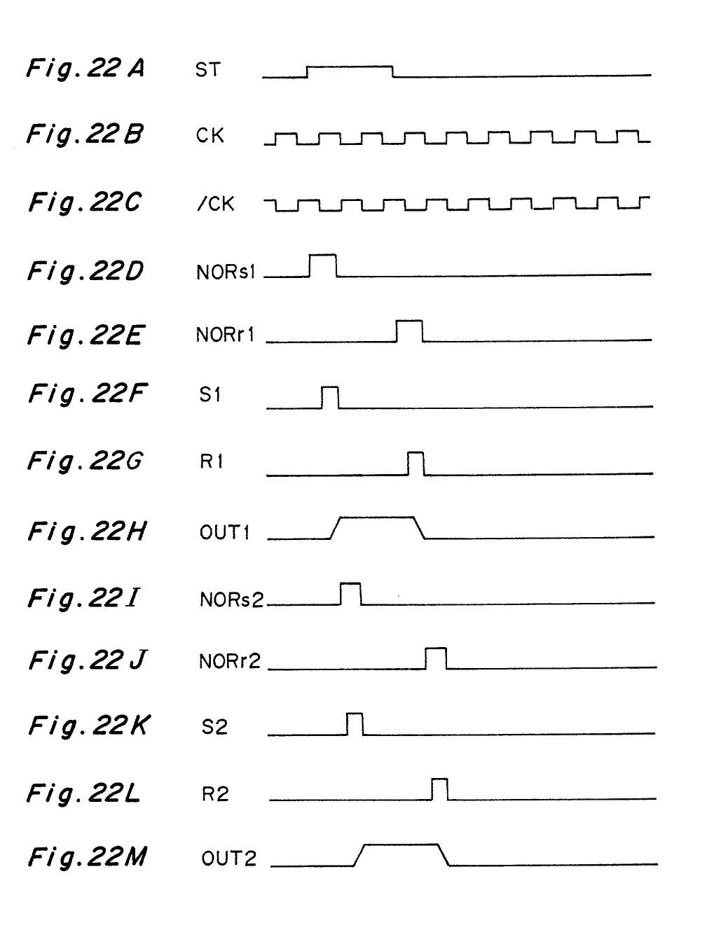

FIGS. 22A through 22M show the signal waveforms of the shift register circuit shown in FIG. 21. In FIGS. 22A through 22M, NOR signals (NORs1 and NORs2 in FIGS. 22D and 22I) that are control signals corresponding to the set signals (S1 and S2 in FIGS. 22F and 22K) become active when the output signal level of the SR-type flip-flop SRFF2 (shown in FIG. 21) of the stage is inactive and the output signal level of the SR-type flip-flop SRFF2 of the preceding stage (start signal ST for only the SR-type flip-flop SRFF2 of the first stage) is active. This indicates that the clock signal CK (clock signal /CK for each even-number register block BLK7) is inputted as the internal set signal S of each flip-flop SRFF2. The NOR signals that are control signals corresponding to the reset signals (R1 and R2 in FIGS. 22G and 22L) become active when the output signal level of the flip-flop of the stage is active and the output signal level of the flip-flop of the preceding stage is inactive. This indicates that the clock signal CK (clock signal /CK for each even-number register block BLK7) is inputted as the reset signal R of each flip-flop SRFF2. It is to be noted that the NOR signals NORs1 and NORr1, the set signal S1, the reset signal R1 and the output signal OUT1 indicate signals relevant to the register block BLK7 of the first stage, while the NOR signals NORs2 and NORr2, the set signal S2, the reset signal R2 and the output signal OUT2 indicate signals relevant to the register block BLK7 of the second stage. Although the signal waveforms of the register block BLK7 of the third and subsequent stages are not shown, the same thing as described above can be said.

As described above, the transfer gates TG81 and TG82 can be made active (brought into the ON-state) when the input signal level and the output signal level of the register block BLK7 differ from each other with a simple construction employing the NOR circuits NORs2 and NORr2 and the inverters IV51 and IV52. The SR-type flip-flop SRFF2 is supplied with the clock signal only in the timing at which the internal state changes, and this allows the period during which the clock signal is inputted to be shortened and allows the loads of the clock signal line to be restrained to the minimum.

Furthermore, the period during which the level shift circuit LS22 operates can also be shortened, and therefore, the consumption of power of the level shift circuit LS22 can be restrained to the minimum.

Although the NOR circuits NORs2 and NORr2 of the inverted outputs are employed as the first and second logic operation sections in the eighth embodiment, it is acceptable to employ an OR circuit whose output is not inverted by the control input conditions and the like of the transfer gate. The first and second logic operation sections can also be provided by combining other logic operators.

(Ninth Embodiment)

If the clock input terminal of each flip-flop is connected only to a transfer gate in the constructions of the shift register circuits of FIG. 17 and FIG. 21, then the clock input terminal of each flip-flop is brought into a floating state when the transfer gate is in the OFF-state. In the above case, if the potential level of the clock input terminal is shifted in the undesirable direction due to an external noise or an internal leak current, then the shift register circuit will malfunction. In this case, the possibility of the occurrence of malfunction is reduced since the period during which the floating state is present becomes short when the operation frequency of the shift register circuit is high. The possibility of the occurrence of malfunction is also similarly reduced since the potential level is relatively stable when the internal parasitic capacitance is sufficiently large. Accordingly, it is also effective to intentionally add a capacitance to the clock input terminal. However, it is preferable to adopt another stabilizing means since the addition of a capacitance becomes a load of circuit operation.

In order to prevent the possible occurrence of the malfunction as described above, it is preferable to set the clock input terminal of the flip-flop to a level at which the flip-flop is brought into a latched state when the transfer gate is in the OFF-state.

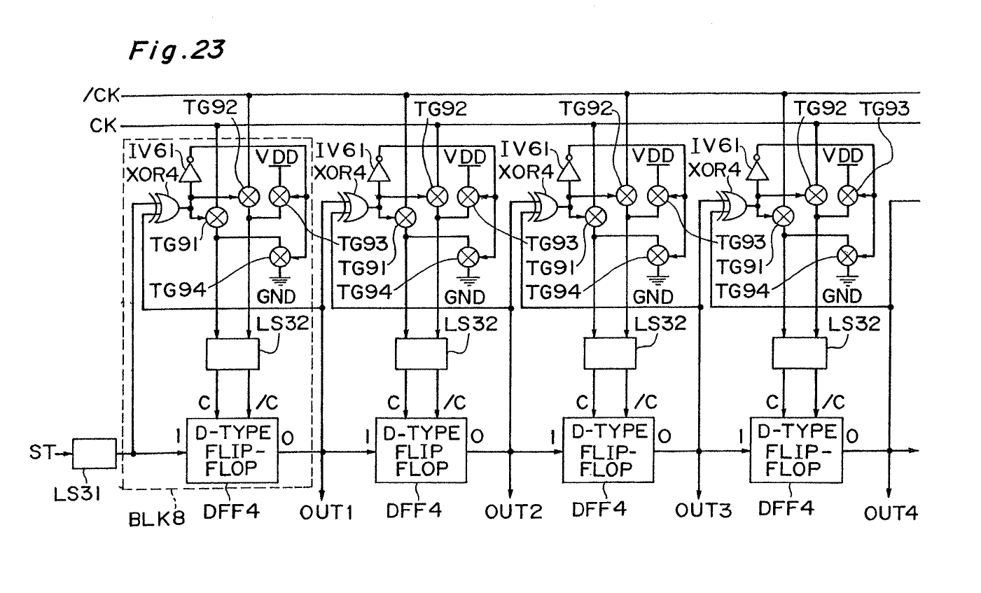

FIG. 23 is a block diagram showing the construction of a shift register circuit in which the flip-flop is brought into the latched state when the transfer gate of the ninth embodiment of the present invention is in the OFF-state. This shift register circuit has the same construction as that of the shift register of the seventh embodiment shown in FIG. 17 except for transfer gates TG93 and TG94 and an inverter IV61, which will be described later. Although the shift register circuit shown in FIG. 23 employs the D-type flip-flops, the same thing can be said for a construction that employs the SR-type flip-flops.

As shown in FIG. 23, this shift register circuit has a plurality of serially connected D-type flip-flops DFF4 (only four are shown in FIG. 23 for the sake of simplicity), transfer gates TG91 and TG92 provided for each D-type flip-flop DFF4, a level shift circuit LS31 the input terminal of which receives the start signal ST and the output terminal of which is connected to the input terminal of the flip-flop FF4 of the first stage, a level shift circuit LS32 provided for each D-type flip-flop DFF4 and an exclusive-OR circuit XOR4 that serves as a logic operation section provided for each D-type flip-flops DFF4. The input terminal of the D-type flip-flop DFF4 is connected to one input terminal of the exclusive-OR circuit XOR4, the output terminal of the D-type flip-flop DFF4 is connected to the other input terminal of the exclusive-OR circuit XOR4, and the output terminal of the exclusive-OR circuit XOR4 is connected to the control input terminals of the transfer gates TG91 and TG92. A register block BLK8 is constructed of the D-type flip-flop DFF4, the transfer gates TG91 and TG92, the exclusive-OR circuit XOR4 and the level shift circuit LS32.

Although the exclusive-OR circuit XOR4 is employed as the logic operation section in the ninth embodiment, the logic operation section can also be provided by combining other logic operators.

The transfer gate TG91 is controlled to be turned on and off by an exclusive-OR signal outputted from the exclusive-OR circuit XOR4, and the clock signal CK (clock signal /CK for each even-number register block BLK8) is inputted to the level shift circuit LS32 via this transfer gate TG91. The clock signal CK (clock signal /CK for each even-number register block BLK8) shifted in level (expanded in amplitude) by the level shift circuit LS32 is inputted to the D-type flip-flop DFF4. On the other hand, the transfer gate TG92 is controlled to be turned on and off by an exclusive-OR signal outputted from the exclusive-OR circuit XOR4, and the clock signal /CK (clock signal CK for each even-number register block BLK8) is inputted to the level shift circuit LS32 via this transfer gate TG92. The clock signal /CK (clock signal CK for each even-number register block BLK8) shifted in level (expanded in amplitude) by the level shift circuit LS32 is inputted to the D-type flip-flop DFF4. Further, a transfer gate TG94 that serves as a retainment signal circuit for inputting a ground-level retainment signal to the clock input terminal of the D-type flip-flop DFF4 is provided (on the flip-flop side) in the stage subsequent to the transfer gate TG91, and a transfer gate TG93 that serves as a retainment signal circuit for inputting a power-source-level retainment signal to the clock input terminal of the D-type flip-flop DFF4 is provided (on the flip-flop side) in the stage subsequent to the transfer gate TG92.

In the shift register circuit having the above-mentioned construction, the clock input terminal C (clock signal corresponding to signal transfer) of the D-type flip-flop DFF4 comes to have the ground level (becomes inactive) when the transfer gate TG91 of the clock signal is off (non-conductive), while the clock input terminal /C (clock signal corresponding to signal latching) of the D-type flip-flop DFF4 comes to have the power source level (becomes active) when the transfer gate TG92 of the clock signal is off (non-conductive). By the above operation, the retainment signal that retains the internal state is to be inputted to each D-type flip-flop DFF4 in the period during which the clock signals CK and /CK are not inputted to the D-type flip-flop DFF4, and therefore, the stability of operation can be secured.

(Tenth Embodiment)

In the shift register circuits of the six through ninth embodiments, each level shift circuit is not required to operate in the period during which the transfer gate is off, and therefore, it is preferable to keep the state in which no current flows in terms of consumption of power.

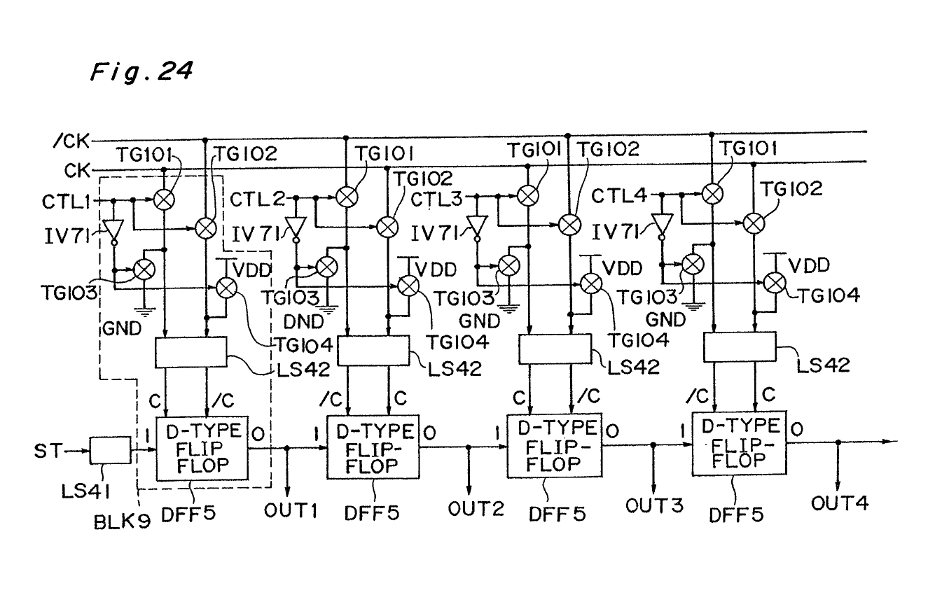

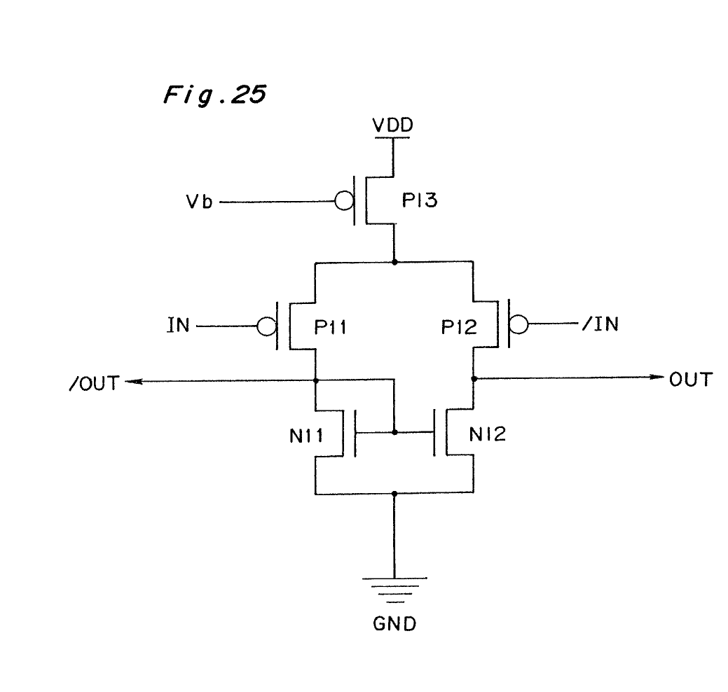

Accordingly, in the shift register circuit of this tenth embodiment of the present invention, the input signal level is fixed to the power source potential or the ground potential as shown in FIG. 24 so as to prevent the flow of current in the case where the level shift circuit of the type in which a stationary current flows is employed as shown in FIG. 19, FIG. 20 and FIG. 25.

As shown in FIG. 24, this shift register circuit has a plurality of serially connected flip-flops DFF5, transfer gates TG101 and TG102 provided for each D-type flip-flop DFF5, a level shift circuit LS41 the input terminal of which receives the start signal ST and the output terminal of which is connected to the input terminal of the D-type flip-flop DFF5 of the first stage, a level shift circuit LS42 provided for each D-type flip-flop DFF5, an inverter IV71 to the input terminal of which is inputted a control signal and transfer gates TG103 and TG104 that serve as an OFF-state signal circuit control input terminals of which are connected to the output terminal of the inverter IV71. One terminal of the transfer gate TG103 is connected between the transfer gate TG101 and the level shift circuit LS42, while the ground GND is connected to the other terminal of the transfer gate TG103. One terminal of the transfer gate TG104 is connected between the transfer gate TG102 and the level shift circuit LS42, and the power source VDD is connected to the other terminal of the transfer gate TG104.

A register block BLK9 is constructed of the D-type flip-flop DFF5, the transfer gates TG101, TG102, TG103 and TG104, the inverter IV71 and the level shift circuit LS42.

The clock signal CK (clock signal /CK for each even-number register block BLK9) is inputted to the level shift circuit LS42 via the transfer gate TG101 that is controlled to be turned on and off by the control signals (CTL1 through CTL4 in FIG. 24), expanded in amplitude by the level shift circuit LS42 whose operation is controlled by the control signals and thereafter inputted to the D-type flip-flop DFF5. On the other hand, the clock signal /CK (clock signal CK for each even-number register block BLK9) is inputted to the level shift circuit LS42 via the transfer gate TG102 that is controlled to be turned on and off by the control signals, expanded in amplitude by the level shift circuit LS42 whose operation is controlled by the control signals and thereafter inputted to the D-type flip-flop DFF5.

In the above-mentioned shift register circuit, the ground potential is inputted to the input terminal of the level shift circuit LS42 by the added transfer gate TG103 in the period during which the transfer gate TG101 is off (non-conductive). The power source potential is inputted to the input terminal of the level shift circuit LS42 by the added transfer gate TG104 in the period during which the transfer gate TG102 is off (non-conductive).

FIG. 25 shows a concrete circuit of the level shift circuit LS42 of this tenth embodiment. This level shift circuit shown in FIG. 25 is a sort of differential amplifier, which amplifies and outputs an amplitude difference between input signals IN and /IN. In this level shift circuit, as shown in FIG. 25, the input signal IN is inputted to the gate of a PMOS transistor P11, and the drain of a PMOS transistor P13 is connected to the source of the PMOS transistor P11. The power source VDD is connected to the source of the PMOS transistor P13, and a signal Vb from a fixed bias source (not shown) is inputted to the gate of the PMOS transistor P13. The source of a PMOS transistor P12 is connected to the source of the PMOS transistor P11, and the input signal /IN is inputted to the gate of the PMOS transistor P12. The drain of an NMOS transistor N11 is connected to the drain of the PMOS transistor P11, and the source of the NMOS transistor N11 is connected to the ground GND. On the other hand, the drain of an NMOS transistor N12 is connected to the drain of the PMOS transistor P12, and the source of the NMOS transistor N12 is connected to the ground GND. The gate and drain of the NMOS transistor N11 are connected together, and the gates of the NMOS transistors N11 and N12 are connected together. An output signal /OUT is outputted from the drain of the PMOS transistor P11, and an output signal OUT is outputted from the drain of the PMOS transistor P12.

The terminals IN, /IN, OUT and /OUT of the level shift circuit shown in FIG. 25 correspond to an input terminal located on the upper left-hand side, an input terminal located on the upper right-hand side, an output terminal located on the lower left-hand side and an output terminal located on the lower right-hand side, respectively, of the level shift circuit LS42 shown in FIG. 24.

As described above, by fixing the input signal level of the level shift circuit LS42 to the power source potential or the ground potential by means of the transfer gates TG103 and TG104 that serve as OFF-state signal circuits when the transfer gates TG101 and TG102 are in the OFF-state, the consumption of current of the level shift circuit LS42 can be reduced with no current flowing through the level shift circuit LS42.

(Eleventh Embodiment)

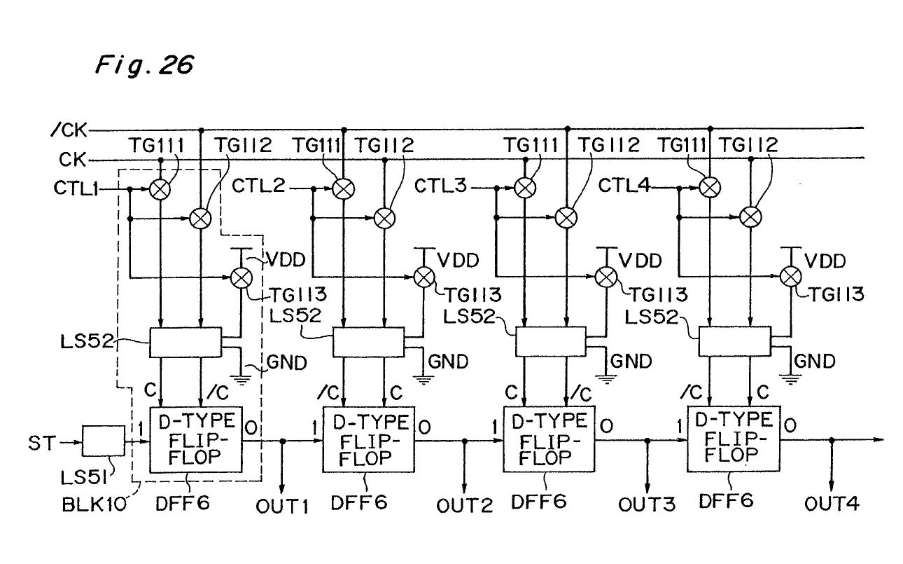

FIG. 26 shows a block diagram of a shift register circuit of the eleventh embodiment of the present invention. In this shift register circuit, as shown in FIG. 26, a power source line for supplying the power to the level shift circuit is cut off by a control signal in a period during which the transfer gate is in the OFF-state, preventing the flow of a current through the level shift circuit.

As shown in FIG. 26, this shift register circuit has a plurality of serially connected D-type flip-flops DFF6, transfer gates TG111 and TG112 provided for each D-type flip-flop DFF6, a level shift circuit LS51 the input terminal of which receives the start signal ST and the output terminal of which is connected to the input terminal of the D-type flip-flop DFF6 of the first stage, a level shift circuit LS52 provided for each D-type flip-flop DFF6 and a transfer gate TG113 that serves as a disconnecting circuit having one terminal connected to the power source VDD and the other terminal connected to a power source terminal of the level shift circuit LS52. The power supplied to the level shift circuit LS52 is controlled on the basis of control signals (CTL1 through CTL4 in FIG. 26) inputted to the transfer gate TG113. A register block BLK10 is constructed of the D-type flip-flop DFF6, the transfer gates TG111, TG112 and TG113 and the level shift circuit LS52. It is to be noted that the level shift circuit LS52 of this eleventh embodiment has the same construction as that of the tenth embodiment of FIG. 25.

As described above, by cutting off the current path of the level shift circuit LS52 by means of the transfer gate TG113 that serves as the disconnecting circuit when the transfer gates TG111 and TG112 are in the OFF-state, the consumption of current of the level shift circuit LS52 can be reduced.

Although the power source line of the level shift circuit LS52 is cut off by the transfer gate TG113 that serves as the disconnecting circuit in the eleventh embodiment, the ground line of the level shift circuit may be cut off by a disconnecting circuit.

(Twelfth Embodiment)

An image display device of the twelfth embodiment of the present invention has a construction similar to that of the image display device of the fifth embodiment shown in FIG. 10, and the same components are denoted similarly to FIG. 10 with no description provided for the components.

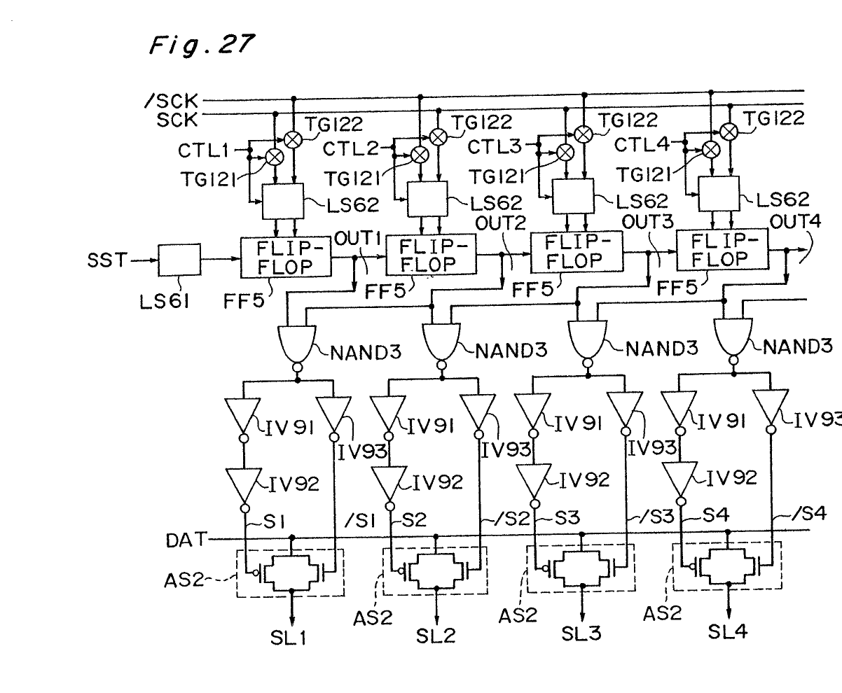

FIG. 27 shows the construction of a data signal line drive circuit SD1 of the image display device of this twelfth embodiment. This data signal line drive circuit SD1 has the same construction as that of the data signal line drive circuit of the fifth embodiment except for the level shift circuit.

As shown in FIG. 27, this data signal line drive circuit has a plurality of serially connected flip-flops FF5, transfer gates TG121 and TG122 provided for each flip-flops FF5, a level shift circuit LS61 for shifting the level of a start signal SST inputted to the flip-flop FF5 of the first stage and a level shift circuit LS62 provided for each flip-flop FF5.

A clock signal SCK (clock signal /SCK for each even-number flip-flop FF5) is inputted to the level shift circuit LS62 via the transfer gate TG121, and the clock signal SCK (clock signal /SCK for each even-number flip-flop FF5) having a level shifted by the level shift circuit LS62 is inputted to the flip-flop FF5. On the other hand, a clock signal /SCK (clock signal SCK for each even-number flip-flop FF5) is inputted to the level shift circuit LS62 via the transfer gate TG122, and the clock signal /SCK (clock signal SCK for each even-number flip-flop FF5) having a level shifted by the level shift circuit LS62 is inputted to the flip-flop FF5.

The output terminal of the flip-flop FF5 is connected to one input terminal of a NAND circuit NAND3, and the output terminal of the flip-flop FF5 of the subsequent stage is connected to the other input terminal of the NAND circuit NAND3. The output terminal of the NAND circuit NAND3 is connected to one control input terminal of an analog switch AS2 via serially connected inverters IV91 and IV92, and the output terminal of the NAND circuit NAND3 is connected to the other control input terminal of the analog switch AS2 via an inverter IV93. A video signal DAT is inputted to the input terminal of the analog switch AS2, and the analog switch AS2 is turned on and off by control inputs (S1 through S4 and /S1 through /S4 in FIG. 27) to output the video signal DAT to data signal lines (SL1 through SL4 in FIG. 27).

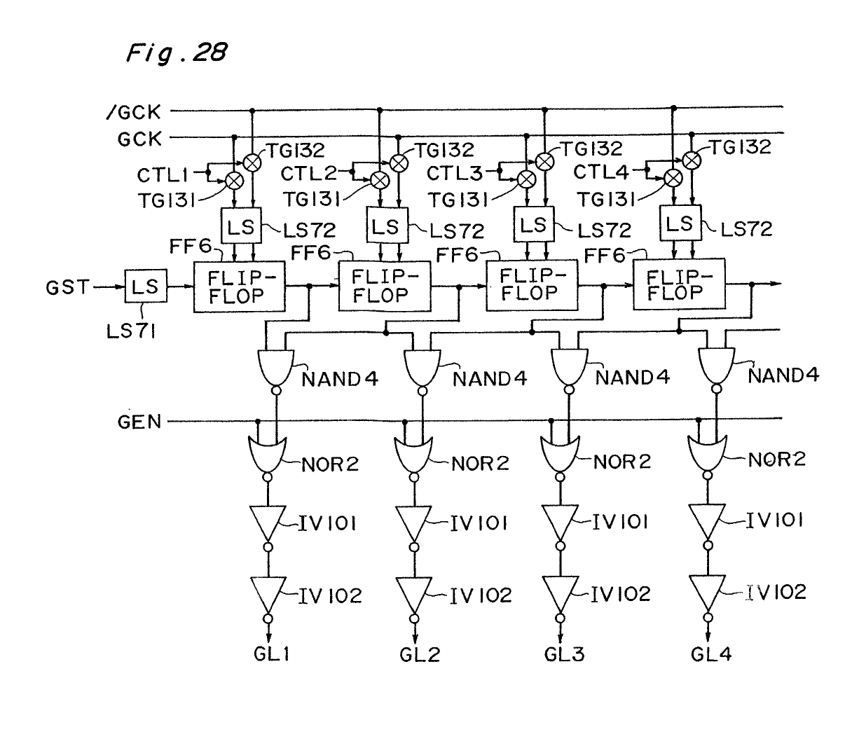

FIG. 28 shows the construction of the scanning signal line drive circuit GD1. This scanning signal line drive circuit employs a shift register circuit of the same construction as that of the scanning signal line drive circuit of the fifth embodiment shown in FIG. 12 except for the level shift circuit.

As shown in FIG. 28, this scanning signal line drive circuit has a plurality of serially connected flip-flops FF6, transfer gates TG131 and TG132 provided for each flip-flop FF6, a level shift circuit LS71 for shifting the level of a start signal GST inputted to the flip-flop FF6 of the first stage and a level shift circuit LS72 provided for each flip-flop FF6. The output terminal of the flip-flop FF6 is connected to one input terminal of a NAND circuit NAND4, and the output terminal of the flip-flop FF6 of the subsequent stage is connected to the other input terminal of the NAND circuit NAND4. The output terminal of the NAND circuit NAND4 is connected to one input terminal of a NOR circuit NOR2, and an enable signal GEN is inputted to the other input terminal of the NOR circuit NOR2. The input terminal of an inverter IV101 is connected to the output terminal of the NOR circuit NOR2, and the output terminal of the inverter IV101 is connected to the input terminal of the inverter IV102. A scanning signal is outputted from the inverter IV102 to scanning signal lines (GL1 through GL4 in FIG. 28).

In this case, by employing the shift register circuit of the eleventh embodiment shown in FIG. 26 for the data signal line drive circuit SD1 or the scanning signal line drive circuit GD1, the capacitive load of the clock signal line SCK or GCK is reduced, and the period during which a current flows through the level shift circuit can be shortened, allowing the achievement of consumption power reduction and cost reduction.

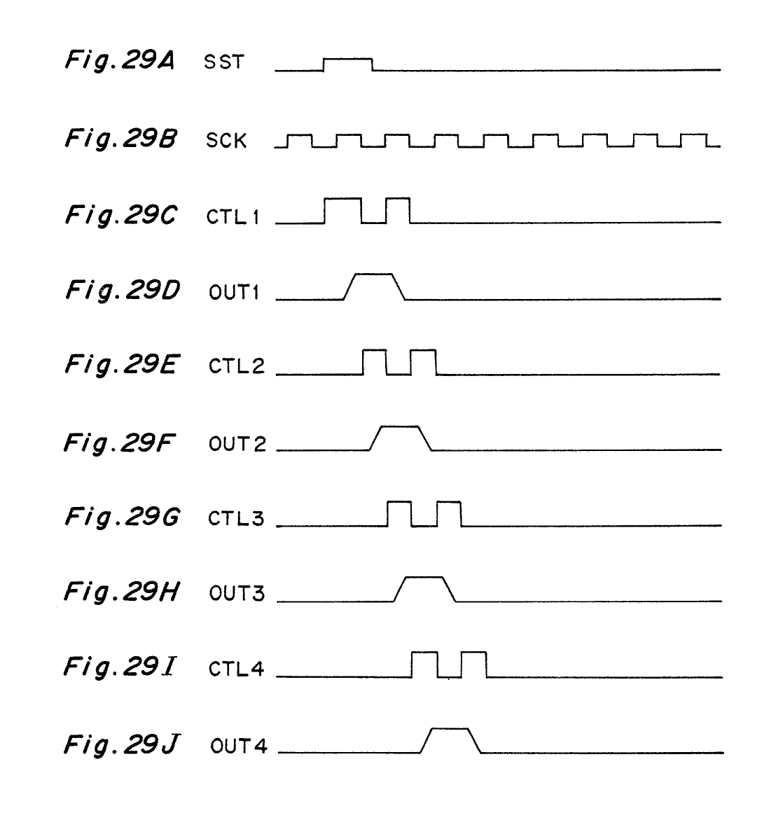

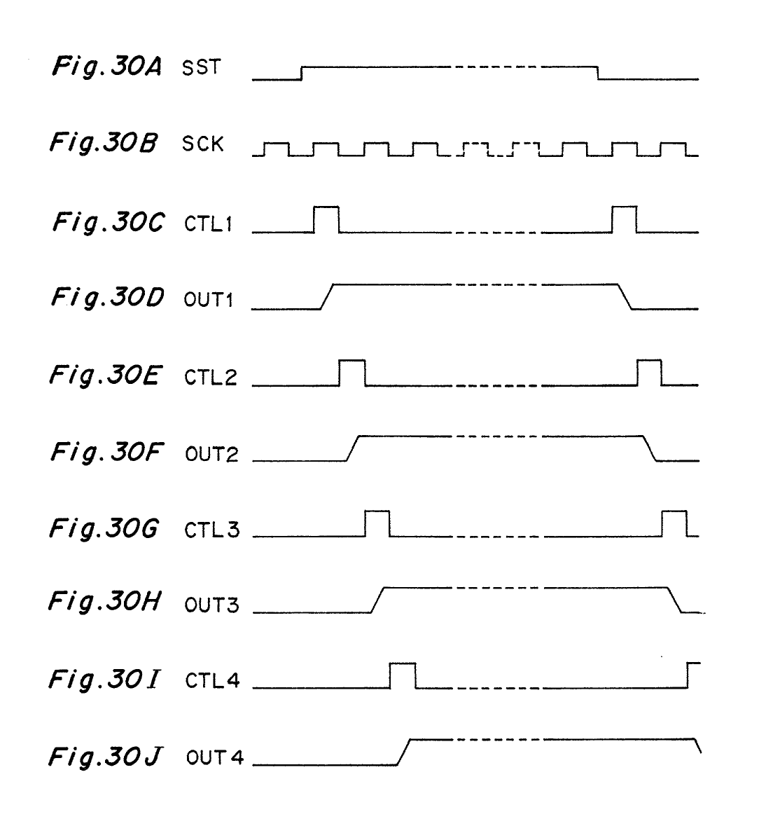

FIGS. 29A through 29J and FIGS. 30A through 30J are charts showing the internal waveforms of the data signal line drive circuit shown in FIG. 27.

In contrast to the fact that the width of the pulse to be transferred through the shift register circuit is the minimum (one cycle of the clock signal SCK) in FIGS. 29A through 29J, the pulse width is widened in FIGS. 30A through 30J. However, despite that the pulse width is varied, the period during which the control signal of the transfer gate is active, i.e., the period during which the clock signal SCK is inputted is identical. Accordingly, this indicates that the loads of the clock signal line can be restrained to the minimum (two or less) with whatever pulse width.

For example, the following two points can herein be enumerated as the merits of changing the pulse width.

One point is to optimize the width of a sampling pulse (pulse for writing image data into the data signal line) of the data signal line drive circuit. If the width of the sampling pulse is narrow, then the video signal cannot sufficiently be written into the data signal line, degrading the display quality. However, if the sampling pulse width is made excessively long, then the load of the video signal line becomes heavy, possibly causing an increase in the load of an external IC (video amplifier or the like). Therefore, it is preferable to adopt the optimum sampling pulse according to the specifications (display size, resolution, driving frequency, driving voltage and so on) of the image display device. In the construction of this twelfth embodiment, the loads of the clock signal line can sufficiently be reduced with respect to the sampling pulse width optimized as above.

The other point is the writing of the side black (black display regions at the top and bottom of the video region) in a wide screen display mode. The writing of the side black video signal (black signal), which can also be executed by means of the data signal line drive circuit, is required to be executed in the vertical retrace line interval, and the time of the interval is insufficient if the driving speed (sampling period) is the same as that of normal image display. Therefore, it is important to collectively write the video signal (side black signal) instead of writing the signal every data signal line. For this purpose, the outputs of the flip-flops constituting the shift register circuit are required to be all activated by sufficiently increasing the width of the pulse to be transferred inside the shift register circuit. According to the construction of this twelfth embodiment, the loads of the clock signal line can sufficiently be reduced even when the pulse width is extremely long like this.

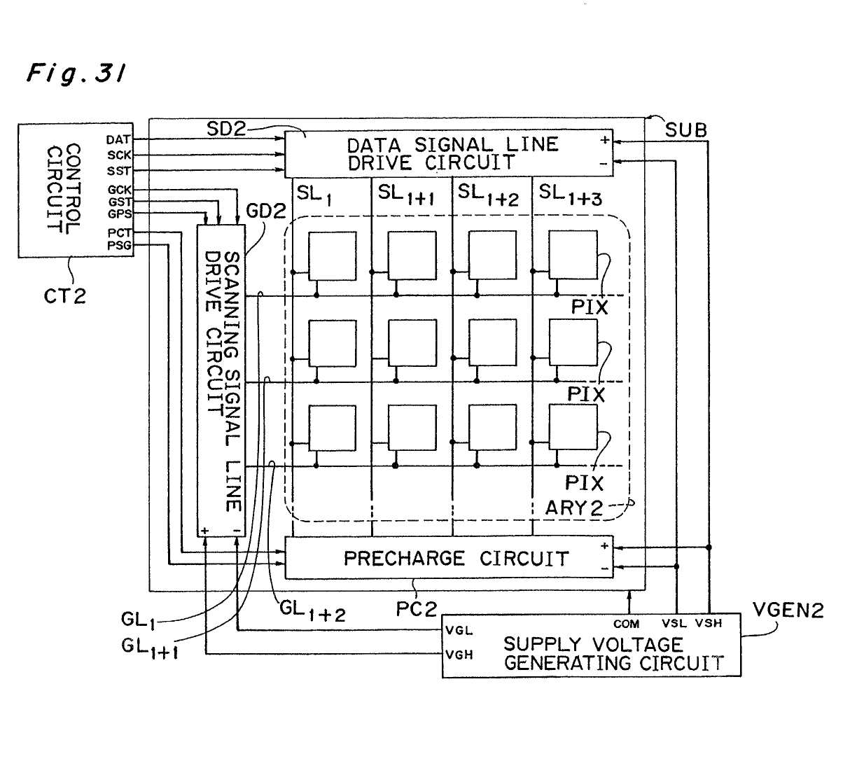

FIG. 31 shows another construction of the image display device of the present invention.

In the image display device shown in FIG. 31, pixels PIX, a data signal line drive circuit SD2 and a scanning signal line drive circuit GD2 are provided on an identical insulating substrate SUB (driver monolithic structure) and are driven by signals from an external control circuit CT2 and a driving power source from an external supply voltage generating circuit VGEN2.

In the image display device having the above-mentioned construction, the data signal line drive circuit SD2 and the scanning signal line drive circuit GD2 are arranged while being widely distributed in a region of a length almost equal to that of the screen (display region), and therefore, the wiring length of the clock signal and so on is extremely long. Accordingly, the load capacitance of the clock signal line and so on is also extremely large, and therefore, the effect of reducing the load capacitance of the clock signal line by virtue of the local input of the clock signal also becomes great.

By virtue of the (monolithic) formation of the data signal line drive circuit SD2 and the scanning signal line drive circuit GD2 on the same insulating substrate SUB as that of the pixels PIX, the fabricating cost and mounting cost of the drive circuits can be reduced further than when the components are separately mounted, and there is produced the effect of increasing the reliability.

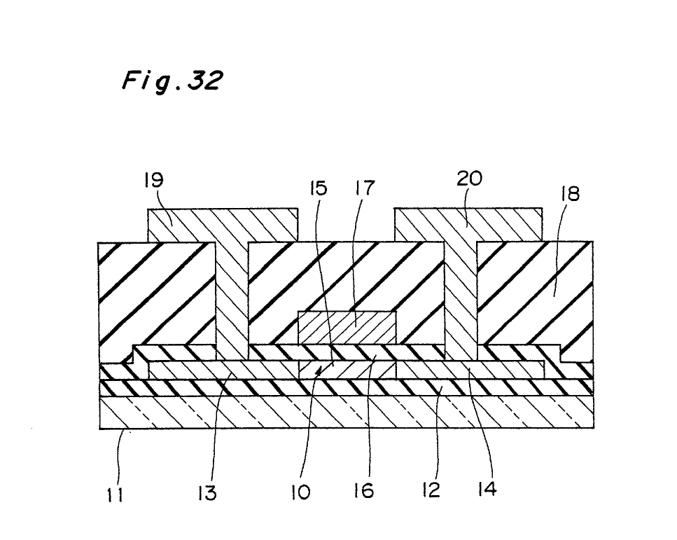

FIG. 32 is a sectional view showing the structure of a polysilicon thin film transistor constituting part of the image display device of the present invention.

As shown in FIG. 32, a silicon oxide film 12 is formed on an insulating substrate 11, and a patterned polysilicon thin film 10 is formed on the silicon oxide film 12. A source region 13, an active region 15 and a drain region 14 are formed in the polysilicon thin film 10. A gate insulating film 16 is formed on the exposed region of the polysilicon thin film 10 and the insulating substrate 11, and a gate electrode 17 is formed in a region corresponding to the active region 15 of the polysilicon thin film 10 located on the gate insulating film 16. An interlayer insulating film 18 covering the whole substrate is formed, a source electrode 19 is formed on the source region 13, and a drain electrode 20 is formed on the drain region 14.

The polysilicon thin film transistor shown in FIG. 32 has a forward stagger (top gate) structure employing the polysilicon thin film 10 on the insulating substrate 11 as an active layer. However, the shift register circuit of the present invention is not limited to this, and a reverse stagger structure or another structure may be employed. Although the polysilicon thin film transistor is employed as the active elements of the data signal line drive circuit and the scanning signal line drive circuit, the polysilicon thin film transistor may be employed at least in the data signal line drive circuit.

By employing the above-mentioned polysilicon thin film transistor, a scanning signal line drive circuit and a data signal line drive circuit having practicable driving abilities can be constructed on the substrate identical to that of the pixel array through almost same fabricating processes.

The polysilicon thin film transistor has a driving ability one to two orders smaller than that of the single crystal silicon transistor (MOS transistor), and therefore, the constituent transistors should be increased in size when constructing a shift register circuit, and consequently, the input load capacitance also tends to be increased. Therefore, the effect of reducing the load capacitance of the clock signal line due to the local input of the clock signal also becomes great.

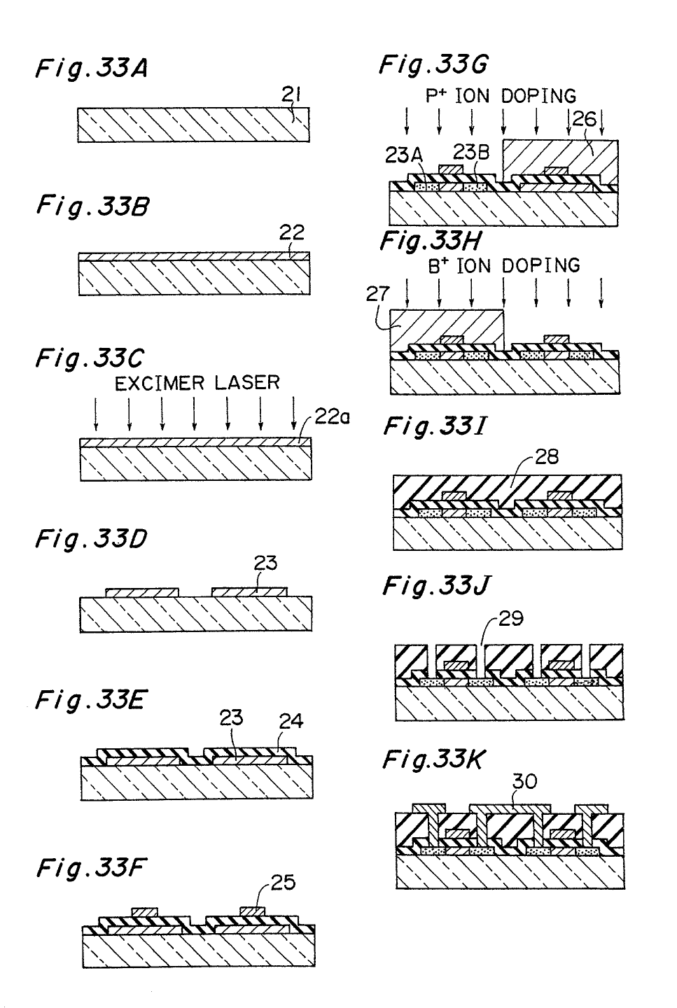

FIGS. 33A through 33K are structural sectional views showing the fabricating processes of the polysilicon thin film transistor shown in FIG. 32. It is to be noted that the silicon oxide film on the insulating substrate is not shown in FIGS. 33A through 33K for the purpose of providing a view that is easy to see.

The fabricating processes for fabricating the polysilicon thin film transistor at a temperature of not higher than 600° C. will be simply described below.

First of all, in FIGS. 33A and 33B, an amorphous silicon thin film 22 is deposited on a glass substrate 21. Next, excimer laser light is radiated to the amorphous silicon thin film 22 as shown in FIG. 33B, forming a polysilicon thin film 22a as shown in FIG. 33C. Next, the polysilicon thin film 22a shown in FIG. 33C is patterned into the desired shape, forming an active region 23 as shown in FIG. 33D. Next, a gate insulating film 24 made of silicon dioxide is formed on the active region 23 and the glass substrate 21 excluding the active region 23 as shown in FIG. 33E. Further, a gate electrode 25 of a thin film transistor is formed of aluminum or the like as shown in FIG. 33F, and thereafter, impurities (phosphorus for the n-type region and boron for the p-type region) are implanted into the source and drain regions 23A and 23B of the thin film transistor as shown in FIG. 33G and 33H. Subsequently, an interlayer insulating film 28 made of silicon dioxide, silicon nitride or the like is deposited as shown in FIG. 33I. Next, a contact hole 29 is opened as shown in FIG. 33J, and thereafter, a metal line 30 made of aluminum or the like is formed as shown in FIG. 33K. This thin film transistor fabricating process has a maximum process temperature of 600° C. when forming the gate insulating film, and therefore, a high heat resistance glass such as the 1737 glass of U.S. Corning Corp. can be employed.

According to the liquid crystal display device, a transparent electrode (in the case of a transmission type liquid crystal display device) and a reflection electrode (in the case of a reflection type liquid crystal display device) are subsequently formed via another interlayer insulating film.

In this case, by forming the polysilicon thin film transistor at a temperature of not higher than 600° C. in the fabricating processes shown in FIGS. 33A through 33K, a glass substrate of a large area can be employed at low cost, and therefore, the image display device is allowed to have a reduced cost and a large area.

The shift register circuits and image display devices of the present invention have been described as above on the basis of the first through twelfth embodiments. However, the present invention is not limited to them and can also be applied to other constructions of combinations of the aforementioned embodiments and the like.

As is apparent from the above, according to the shift register circuit of the present invention, in the shift register circuit in which the register blocks that respectively have the flip-flop operating in synchronization with the clock signal and the transfer gate for controlling the clock signal supplied to the flip-flop are connected in series, the capacitive loads of the clock signal line can be reduced by activating the transfer gate for controlling the input of the clock signal only in the specified period during which the output of the flip-flop changes. As a result, the external circuit for supplying the signal to the shift register circuit is allowed to achieve consumption power reduction and cost reduction. Furthermore, by applying this shift register circuit to the data signal line drive circuit or the scanning signal line drive circuit of the image display device, the image display device is allowed to achieve consumption power reduction and cost reduction.

Furthermore, by putting the level shift circuit, which shifts the level of the clock signal having a level lower than the clock signal input level of the flip-flop such that it comes to have the input signal level of the flip-flop, into the operating state only in the specified period during which the output of the register block changes, the capacitive load of the clock signal line can be reduced and the period of operation of the level shift circuit can be shortened. As a result, the consumption power reduction and cost reduction of the external circuit that supplies the clock signal and so on to the shift register circuit as well as the consumption power reduction of the shift register circuit itself can be achieved.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A shift register circuit provided with a plurality of register blocks having a flip-flop that operates in synchronization with a clock signal and a transfer gate for controlling the clock signal supplied to the flip-flop,
the plurality of register blocks being serially connected together, and
the transfer gate being brought into an ON-state every register block only in a specified period during which an output of the flip-flop changes.

2. A shift register circuit as claimed in claim 1, wherein
when a level of an input signal inputted to each register block and a level of an output signal outputted from the register block differ from each other, the transfer gate of the register block is brought into the ON-state.

3. A shift register circuit as claimed in claim 1, wherein
the flip-flop is a D-type flip-flop, and
the register block has a logic operation section for executing a logic operation of an input signal of the register block and an output signal of the register block and controls the transfer gate to be turned on and off based on a signal representing a logic operation result of the logic operation section.

4. A shift register circuit as claimed in claim 1, wherein
the flip-flop is an SR-type flip-flop,
the transfer gate is comprised of a first transfer gate for controlling input of the clock signal inputted to a set terminal of the SR-type flip-flop and a second transfer gate for controlling input of the clock signal inputted to a reset terminal of the SR-type flip-flop, and
the register block has a first logic operation section and a second logic operation section for executing a logic operation of an input signal of the register block and an output signal of the register block, controls the first transfer gate to be turned on and off based on a signal that represents a logic operation result of the first logic operation section and controls the second transfer gate to be turned on and off based on a signal that represents a logic operation result of the second logic operation section.

5. A shift register circuit as claimed in claim 1, wherein
the register block has a retainment signal circuit that inputs to a clock input terminal of the flip-flop of the register block a retainment signal for bringing the output of the flip-flop into a retained state in a period during which the transfer gate is in an OFF-state.

6. An image display device comprising a plurality of pixels arranged in a matrix form, a plurality of data signal lines for supplying image data to be written into the plurality of pixels, a plurality of scanning signal lines for controlling the image data to be written into the pixels, a data signal line drive circuit for driving the data signal lines and a scanning signal line drive circuit for driving the scanning signal lines, wherein
at least one of the data signal line drive circuit and the scanning signal line drive circuit includes the shift register circuit claimed in claim 1.

7. An image display device as claimed in claim 6, wherein
an output pulse width of the data signal line drive circuit is controlled by controlling a pulse width of an input signal inputted to the register block of the first stage of the shift register circuit.

8. An image display device as claimed in claim 7, wherein
a side black region is displayed on an upper side and a lower side of an image display screen by writing a black signal into all the data signal lines while increasing the pulse width of the input signal inputted to the register block of the first stage of the shift register circuit so that all the data signal lines are brought into an active state by the data signal line drive circuit.

9. An image display device as claimed in claim 6, wherein
at least one of the data signal line drive circuit and the scanning signal line drive circuit is formed on a substrate identical to that of the plurality of pixels.

10. An image display device as claimed in claim 9, wherein
an active element constituting at least the data signal line drive circuit is provided by a polysilicon thin film transistor.

11. An image display device as claimed in claim 10, wherein
the active element is formed on a glass substrate through a process at a temperature of not higher than 600° C.

12. A shift register circuit as claimed in claim 1, wherein
the clock signal has a level lower than a clock signal input level of the flip-flop,
the register block has a level shift circuit for shifting a level of the clock signal so that the level of the clock signal becomes not lower than the clock signal input level of the flip-flop, and
the level shift circuit is brought into an operating state every register block only in a specified period during which the output of the flip-flop changes.

13. A shift register circuit as claimed in claim 12, wherein
when a level of an input signal inputted to each register block and a level of an output signal outputted from the register block differ from each other, the transfer gate of the register block is brought into the ON-state, and
when a level of an input signal inputted to each register block and a level of an output signal outputted from the register block differ from each other, the level shift circuit of the register block is brought into an operating state.

14. A shift register circuit as claimed in claim 12, wherein
the register block has a retainment signal circuit that inputs to a clock input terminal of the flip-flop of the register block a retainment signal for bringing the output of the flip-flop into a retained state in a period during which the transfer gate is in an OFF-state.

15. A shift register circuit as claimed in claim 14, wherein
the register block has an OFF-state signal circuit that inputs to the clock input terminal of the level shift circuit an OFF-state signal of a level at which no current flows through the level shift circuit in the period during which the transfer gate is in the OFF-state.

16. A shift register circuit as claimed in claim 14, wherein
the level shift circuit is connected to a power source line and a ground line, and
the register block has a disconnecting circuit for disconnecting either one of the power source line and the ground line of the level shift circuit in the period during which the transfer gate is in the OFF-state.

17. A shift register circuit as claimed in claim 12, wherein
the flip-flop is a D-type flip-flop, and
the register block has a logic operation section for executing a logic operation of an input signal and an output signal of the register block and controls the transfer gate to be turned on and off based on a signal representing a logic operation result of the logic operation section.

18. A shift register circuit as claimed in claim 12, wherein
the flip-flop is an SR-type flip-flop,
the transfer gate is comprised of a first transfer gate for controlling the input of the clock signal inputted to a set terminal of the SR-type flip-flop and a second transfer gate for controlling the input of the clock signal inputted to a reset terminal of the SR-type flip-flop, and
the register block has a first logic operation section and a second logic operation section for executing a logic operation of an input signal and an output signal of the register block, controls the first transfer gate to be turned on and off based on a signal that represents a logic operation result of the first logic operation section and controls the second transfer gate to be turned on and off based on a signal that represents a logic operation result of the second logic operation section.

19. An image display device comprising a plurality of pixels arranged in a matrix form, a plurality of data signal lines for supplying image data to be written into the pixels, a plurality of scanning signal lines for controlling the image data to be written into the pixels, a data signal line drive circuit for driving the data signal lines and a scanning signal line drive circuit for driving the scanning signal lines,
at least one of the data signal line drive circuit and the scanning signal line drive circuit includes the shift register circuit claimed in claim 12.

20. An image display device as claimed in claim 19, wherein
an output pulse width of the data signal line drive circuit is controlled by controlling a pulse width of an input signal inputted to the register block of the first stage of the shift register circuit.

21. An image display device as claimed in claim 19, wherein
a side black region is displayed on an upper side and a lower side of an image display screen by writing a black signal into all the data signal lines while increasing the pulse width of the input signal inputted to the register block of the first stage of the shift register circuit so that all the data signal lines are brought into an active state by the data signal line drive circuit.

22. An image display device as claimed in claim 19, wherein
at least one of the data signal line drive circuit and the scanning signal line drive circuit is formed on a substrate identical to that of the pixels.

23. An image display device as claimed in claim 22, wherein
an active element constituting at least the data signal line drive circuit is provided by a polysilicon thin film transistor.

24. An image display device as claimed in claim 23, wherein
the active element is formed on a glass substrate through a process at a temperature of not higher than 600° C.
